(19) United States
(12) Patent Application Publication
(10) Pub. No.: US 2022/0352059 A1
(43) Pub. Date: Nov. 3, 2022

(54) SEMICONDUCTOR PACKAGE AND MANUFACTURING METHOD THEREOF

(71) Applicant: Nepes CO., LTD., Samseong-myeon (KR)

(72) Inventors: Jong Heon KIM, Seongnam-si (KR); Young Mo LEE, Cheongju-si (KR); Nam Chul KIM, Cheongju-si (KR); Yong Tae KWON, Cheongju-si (KR); Chi Jung SONG, Daejeon (KR); Yong Soo KIM, Seoul (KR); Yong Ho KWON, Cheongju-si (KR)

(21) Appl. No.: 17/730,862

(22) Filed: Apr. 27, 2022

(30) Foreign Application Priority Data
Apr. 27, 2021 (KR) 10-2021-0054503

(51) Int. Cl. H01L 23/498; H01L 23/00; H01L 21/48

(52) U.S. Cl. CPC H01L 23/49816; H01L 24/16; H01L 24/08; H01L 21/4853; H01L 21/486; H01L 23/49838; H01L 24/96; H01L 24/97; H01L 2224/16235; H01L 2224/08235; H01L 2924/3511; H01L 2924/3512; H01L 2924/182; H01L 23/49866; H01L 23/49822; H01L 21/4857; H01L 2224/95001

(57) ABSTRACT

A semiconductor package and manufacturing method is disclosed. The semiconductor package includes a semiconductor chip having a plurality of chip terminals formed on one surface thereof, a redistribution layer electrically connected to the chip terminal and extending outwardly from a side surface of the chip to electrically connect the chip terminal to an external device, an external pad provided on the insulating layer, formed to be in contact with the redistribution layer exposed from the insulating layer to be electrically connected to the redistribution layer, and exposed to an upper side of the insulating layer; an external connection terminal formed on the external pad and contacting an external device, a protective layer formed to surround at least one surface and a side surface of the chip, and an insulating layer formed to cover the redistribution layer.

### CROSS REFERENCE TO RELATED APPLICATIONS

This application claims priority to and the benefit of Korean Application No. 10-2021-0054503, filed Apr. 27, 2021.

### FIELD OF THE DISCLOSURE

The present invention relates to a semiconductor package and manufacturing method thereof.

### BACKGROUND

In general, semiconductor chips manufactured by performing various semiconductor processes on a wafer are subjected to a semiconductor package process to manufacture a semiconductor package. Recently, in order to reduce the production cost of a semiconductor package, a wafer level package technology has been proposed that performs a semiconductor package process at the wafer level and individualizes the wafer level semiconductor package that has undergone the semiconductor package process into individual units.

FIG. 1 is a view illustrating a difference in thermal expansion between a semiconductor package and a board.

Meanwhile, referring to FIG. 1, after the semiconductor package 10 is manufactured, it may be mounted on an external device using its own external connection terminal 11. For example, the external device may be a board 20 or the like, such as a printed circuit board or the like. In this case, a difference in thermal expansion (CTE1≠CTE2, where CTE is an abbreviation of Coefficient Of Expansion and refers to a coefficient of thermal expansion) occurring between the semiconductor package 10 and the board 20 may affect the external connection terminal 11 of the semiconductor package 10. In particular, when repeated deformation occurs between the semiconductor package 10 and the board 20 due to the difference in thermal expansion, the conventional semiconductor package 10 has a problem in that its external connection terminal 11 may eventually crack as fatigue is increased.

Since the total cost of semiconductors is rising and the limit to lowering the cost of the front-end process has been reached, there is a growing need to lower costs in packaging, which is a post-end process.

In addition, the number of input/output (I/O) terminals required for semiconductors is increasing due to the high performance of various mobile devices.

In such a situation, a wafer level package technology that performs a semiconductor package process at the wafer level and separates the wafer level semiconductor package that has undergone the semiconductor package process into individual units is attracting attention. Fan-out wafer level package (FOWLP) or fan-out panel level package (FOPLP) is a technology that directly mounts the chip 10 on a wafer rather than a PCB. According to FOWLP and FOPLP, the manufacturing cost of the semiconductor package can be lowered as much as the PCB is not used, and it is possible to miniaturize the semiconductor package, improve the heat dissipation function, reduce power consumption, improve the frequency band, and the like.

FOWLP or FOPLP reconstructs individual dies in wafer form on a carrier and molds them, and then implement them as a package through a fan-out-type redistribution (RDL) process and bumping process, etc.

Meanwhile, in recent years, a process of increasing the size of a semiconductor package to include a larger number of dies is progressing, and a method for manufacturing a semiconductor package capable of achieving such an increase in size more easily and quickly is required.

### SUMMARY

In order to solve the problems of the related art as described above, the present invention is directed to providing a semiconductor package having a structure capable of reducing a difference in thermal expansion with a board to reduce the occurrence of cracks in an external connection terminal thereof, and a method for manufacturing the same.

In addition, the present invention is directed to providing a method for manufacturing a semiconductor package capable of manufacturing a semiconductor package more quickly and conveniently.

The technical problems of the present invention are not limited to the technical problems mentioned above, and other technical problems not mentioned will be clearly understood by those of ordinary skill in the art from the following description.

According to one aspect of the present invention, disclosed is a semiconductor package, comprising: a semiconductor chip having a plurality of chip terminals formed on one surface thereof; a redistribution layer electrically connected to the chip terminal and for electrically connecting the chip terminal to an external device; an insulating layer formed to cover the redistribution layer; an external pad provided on the insulating layer and formed to be electrically connected to the redistribution layer; and an external connection terminal formed on the external pad and contacting an external device; wherein the external connection terminal is formed to be in contact with one surface and a side surface of the external pad exposed to the outside of the insulating layer.

A wetting layer having excellent wettability may be formed on one surface and a side surface of the external pad in contact with the external connection terminal.

The wetting layer may be made of at least one or more of Au, Pd, Ni, Cu, Sn, Ti, Cr, W, and Al.

The external connection terminal may be formed to be in surface contact with an upper surface of the insulating layer on the outer periphery of a side surface of the external pad.

The present invention may further include a conductive post extending in a vertical direction, to electrically connect the chip terminal and the redistribution layer.

The present invention may further include a protective layer formed to cover the one surface of the semiconductor chip, wherein the conductive post penetrates the protective layer covering the one surface of the semiconductor chip to electrically connect the chip terminal and the redistribution layer.

According to another aspect of the present invention, disclosed is a method for manufacturing a semiconductor package, comprising: forming a protective film on one surface of a wafer before a plurality of semiconductor chips are cut, and exposing chip pads of the semiconductor chips; forming conductive posts on the exposed chip pads; and sawing the wafer on which the conductive posts are formed into individual semiconductor chips.

The present invention may further include disposing a plurality of the individual semiconductor chips on which the conductive posts are formed, on a carrier; molding a protective layer on the carrier on which the semiconductor chip is disposed; exposing the conductive post of the semiconductor chip molded to the protective layer; forming a redistribution layer, an external pad, and an external connection terminal on one surface of the protective layer on which the conductive post is exposed; and sawing the protective layer on which the redistribution layer, the external pad, and the external connection terminal are formed, in units of each individual semiconductor chip.

The disposing a plurality of semiconductor chips on the carrier may be a step of disposing a plurality of semiconductor chips on the carrier such that the conductive post faces upward, and the exposing the conductive post of the semiconductor chip molded to the protective layer may be a step of grinding one surface of the molded protective layer so that the conductive post is exposed to the outside.

The disposing a plurality of semiconductor chips on the carrier may be a step of disposing the conductive post in contact with the carrier, and the exposing the conductive post of the semiconductor chip molded to the protective layer may be a step of removing the carrier to expose the conductive post after the protective layer is molded.

The disposing a plurality of semiconductor chips on which the conductive posts are formed, on a carrier may be a step of disposing a plurality of small panels on which a plurality of semiconductor chips are disposed, on the carrier, the small panel having a size smaller than that of the carrier.

The disposing a plurality of semiconductor chips on which the conductive posts are formed, on a carrier may be a step of disposing a plurality of molding bodies on which a plurality of semiconductor chips are molded on the carrier.

The disposing a plurality of the individual semiconductor chips on which the conductive posts are formed, on a carrier may be a step of disposing a plurality of molding bodies formed on a small panel on which a plurality of semiconductor chips are disposed, on the carrier, the small panel having a size smaller than that of the carrier.

The carrier and the small panel may have a circular or quadrangular shape.

A wetting layer may be formed on one surface of the external pad in contact with the external connection terminal by an electroless plating method.

The external connection terminal may be disposed on one surface of the external pad on which the wetting layer is formed, and may be formed to be in contact with one surface and a peripheral side surface of the external pad and a side surface of the external pad.

According to the semiconductor package and the manufacturing method thereof of the present invention, it has a structure capable of reducing a difference in thermal expansion with an external device such as a board, thereby capable of reducing the occurrence of cracks in the external connection terminal.

In addition, according to the present invention, the structure formed by the insulating pattern and the external pad has a structure having a thickness suitable for stress dispersion, thereby improving the stress dispersion effect.

In addition, according to the present invention, a larger-sized semiconductor package can be manufactured in a shorter time, so that productivity can be improved. In addition, according to the present invention, adhesion to the redistribution layer is improved, so that durability may be improved.

The effects of the present invention are not limited to the effects mentioned above, and other effects not mentioned will be clearly understood by those of ordinary skill in the art from the description of the claims.

### BRIEF DESCRIPTION OF THE DRAWINGS

The summary set forth above as well as the detailed description of the preferred embodiments of the present application set forth below may be better understood when read in conjunction with the accompanying drawings. Preferred embodiments are shown in the drawings for the purpose of illustrating the present invention. It should be understood, however, that the present application is not limited to the precise arrangement and means illustrated.

FIG. 1 is a view illustrating a difference in thermal expansion between a semiconductor package and a board.

FIG. 2 is a cross-sectional view of a first semiconductor package 100a according to an exemplary embodiment of the present invention.

FIG. 3 is a cross-sectional view of a second semiconductor package 100b according to an exemplary embodiment of the present invention.

FIG. 4 is a cross-sectional view of a third semiconductor package 100c according to an exemplary embodiment of the present invention.

FIG. 5 is a cross-sectional view of a fourth semiconductor package 100d according to an exemplary embodiment of the present invention.

FIGS. 6 to 17 are cross-sectional views illustrating structures of various types of wiring patterns, external pads, and external connection terminals combined with exemplary embodiments of the present invention.

FIGS. 18 to 19 are cross-sectional views illustrating various types of semiconductor packages that may be modified according to an exemplary embodiment of the present invention.

FIG. 20 is cross-sectional views illustrating a state in which a semiconductor chip is produced from a wafer.

FIG. 21 is cross-sectional views sequentially illustrating a method of manufacturing a semiconductor package in a face-up method.

FIG. 22 is cross-sectional views sequentially illustrating a method of manufacturing a semiconductor package in a face-down method.

### DETAILED DESCRIPTION OF THE EMBODIMENTS

The present invention and method of accomplishing the same may become more apparent through the following detailed description in relation to the accompanying drawings, and accordingly, those of ordinary skill in the art will be able to easily implement the technical idea of the present invention. In addition, in describing the present invention, when it is determined that a detailed description of a related known technology may unnecessarily obscure the subject matter of the present invention, the detailed description will be omitted.

The terms used in this specification are for the purpose of describing embodiments only and are not intended to be limiting the present invention. In this specification, the singular form also includes the plural form in some cases, unless specifically specified in the phrase. In this specification, terms such as “include”, “comprise”, “provide” or “have” do not exclude the presence or addition of one or more other elements other than elements mentioned.

In this specification, the terms such as “or” and “at least one” may represent one of the words listed together or a combination of two or more. For example, “A or B” and “at least one of A and B” may include only one of A or B, or may also include both A and B.

In this specification, descriptions according to “for example”, etc. may not exactly match the information presented, such as the recited properties, variables, or values, and effects such as modifications, including tolerances, measurement errors, limits of measurement accuracy, and other commonly known factors should not limit the modes for carrying out the invention according to the various exemplary embodiments of the present invention.

In this specification, when an element is described as being “connected” or “linked” to another element, it will be understood that it may be directly connected or linked to the other element, but intervening elements may also be present. On the other hand, when an element is referred to as being “directly connected” or “directly linked” to another element, it will be understood that there are no intervening elements present.

In this specification, when an element is described as being “on” or “adjacent to” another element, it will be understood that it may be directly “on” or “connected to” the other element, but intervening elements may also be present. On the other hand, when an element is described as being “directly on” or “directly adjacent to” another element, it will be understood that there are no intervening elements present. Other expressions describing the relationship between the elements, for example, ‘between’ and ‘directly between’, and the like can be construed similarly.

In this specification, terms such as “first” and “second” may be used to describe various elements, but, the above elements should not be limited by the terms above. In addition, the above terms should not be construed as limiting the order of each component, and may be used for the purpose of distinguishing one element from another. For example, a “first element” may be named as a “second element” and similarly, a “second element” may also be named as a “first element.”

Unless otherwise defined, all terms used in this specification may be used with meanings commonly understood by those of ordinary skill in the art. In addition, terms defined in a commonly used dictionary are not interpreted ideally or excessively unless explicitly and specifically defined.

Hereinafter, preferred embodiments according to the present invention will be described in detail with reference to the accompanying drawings.

However, the z-axis direction, which is a direction in which each component of a semiconductor package 100 according to various embodiments of the present invention is stacked, is referred to as a “first direction”, and an x-axis direction or a y-axis direction, which is a direction in a plane perpendicular to the z-axis, is referred to as a “second direction”. In addition, for each component of a semiconductor package 100 according to various embodiments of the present invention, the length in the first direction (z-axis direction) is referred to as “thickness”, “depth” or “height” of the component, and each length in the second direction (x-axis direction and y-axis direction) is referred to as “breadth” and “width” of the component.

The semiconductor package 100 according to various embodiments of the present invention may be a wafer level package (WLP), a fan-out wafer level package (FOWLP), or a panel level package (PLP), but is not limited thereto.

Referring to FIGS. 2 to 19, the semiconductor package 100 according to various embodiments of the present invention may include a semiconductor chip 110, a protective layer 120, an insulating pattern 130, a wiring pattern 140, an external pad 150, and an external connection terminal 160. The semiconductor package 10 may be mounted on an external device using its own external connection terminal 160. For example, the external device may be a board 20 or the like, such as a printed circuit board or the like.

The semiconductor chip 110 may include a plurality of individual devices of various types. For example, a plurality of individual devices may include photoelectronic devices such as microelectronic devices, CMOS transistors (complementary metal-oxide semiconductor transistor), MOSFET (metal-oxide semiconductor field effect transistor), system LSI (large scale integration), and CIS (CMOS imaging sensor), MEMS (micro-electro-mechanical system), elastic wave filter devices, active devices, passive devices, etc., but are not limited thereto.

The semiconductor chip 110 may be a memory semiconductor chip. For example, the memory semiconductor chip may be a volatile memory semiconductor chip such as DRAM (Dynamic Random Access Memory) or SRAM (Static Random Access Memory), or a nonvolatile memory semiconductor chip such as PRAM (Phase-change Random Access Memory), MRAM (Magneto-resistive Random Access Memory), FeRAM (Ferroelectric Random Access Memory) or RRAM (Resistive Random Access Memory), but is not limited thereto.

The semiconductor chip 110 may be a logic chip. For example, the logic chip may be a CPU (Central Processor Unit), MPU (Micro Processor Unit), GPU (Graphic Processor Unit) or AP (Application Processor), but is not limited thereto.

In FIGS. 2 to 5 and the like, the semiconductor package 100 is illustrated as including one semiconductor chip 110, but the semiconductor package 100 may include a plurality of semiconductor chips 110. The plurality of semiconductor chips 110 included in the semiconductor package 100 may be the same type of semiconductor chips or different types of semiconductor chips. In addition, the semiconductor package 100 may be a system in package (SIP) in which different types of semiconductor chips are electrically connected to each other to operate as a single system.

The width and breadth of the semiconductor chip 110 may be about 2 mm to about 10 mm. More specifically, the width and breadth of the semiconductor chip 110 may be about 4 mm to about 7 mm. However, the width and breadth of the semiconductor chip 110 are not limited thereto, and may have more various values. In addition, the thickness of the semiconductor chip 110 may be about 100 μm to about 400 μm. More specifically, the thickness of the semiconductor chip 110 may be about 150 μm to about 350 μm. However, the thickness of the semiconductor chip 110 is not limited thereto, and may have more various values.

The semiconductor chip 110 may include a first surface and a second surface opposite to the first surface. A chip terminal (or referred to as a “chip pad”) 111 may be formed on the first surface of the semiconductor chip 110. The chip terminal 111 may be electrically connected to a plurality of individual devices of various types formed on the semiconductor chip 101. The chip terminal 111 may have a thickness between about 0.5 μm and about 1.5 μm. However, the thickness of the chip terminal 111 is not limited thereto, and may have more various values.

The chip terminal 111 may input/output input/output signals of the semiconductor chip 110. That is, the chip terminal 111 may be electrically connected to the integrated circuit of the semiconductor chip 110 to extend the function of the semiconductor chip 110 to the outside. For example, the chip terminal 111 may be made of a metal having a low specific resistance such as aluminum or copper, but is not limited thereto. In FIG. 2 and the like, it is illustrated that there are two chip terminals 111, but the number of chip terminals 111 is not limited thereto, and may be a larger number.

The protective layer 120 is a layer including a non-conductive material, and may be provided on the second surface of the semiconductor chip 110, may be provided to surround the side surface and the second surface of the semiconductor chip 110, or may be provided to surround the side surface, the first surface, and the second surface of the semiconductor chip 110. The protective layer 120 may be a layer to be formed to block the semiconductor chip 110 from a harmful environment. For example, the protective layer 120 may include various oxides or polymer materials, but is not limited thereto. The protective layer 120 may have a thickness of about 15 μm to about 30 μm on the second surface of the semiconductor chip 110. However, the thickness of the protective layer 120 is not limited thereto, and may have more various values. In addition, the protective layer 120 may be formed of a plurality of layers 120a and 120b.

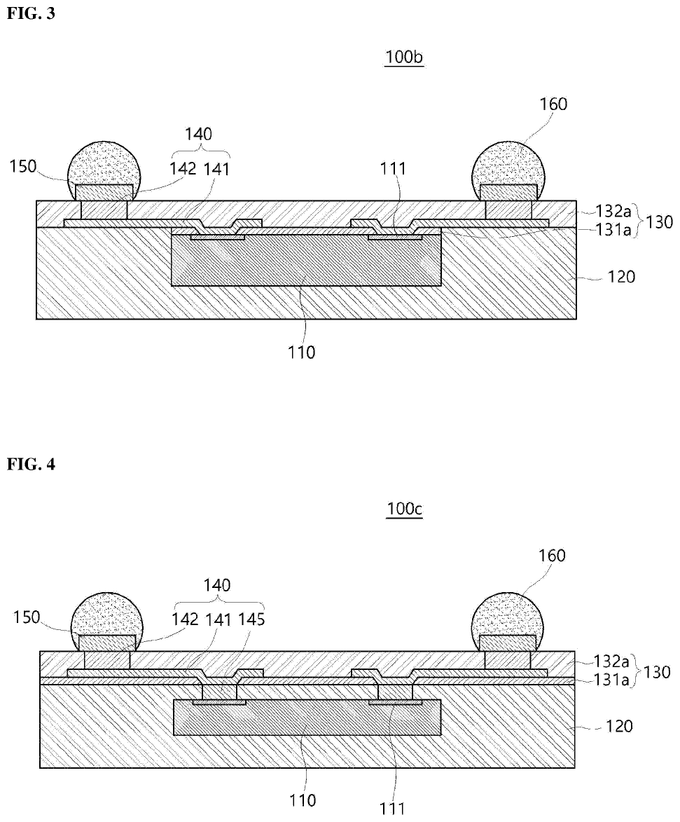

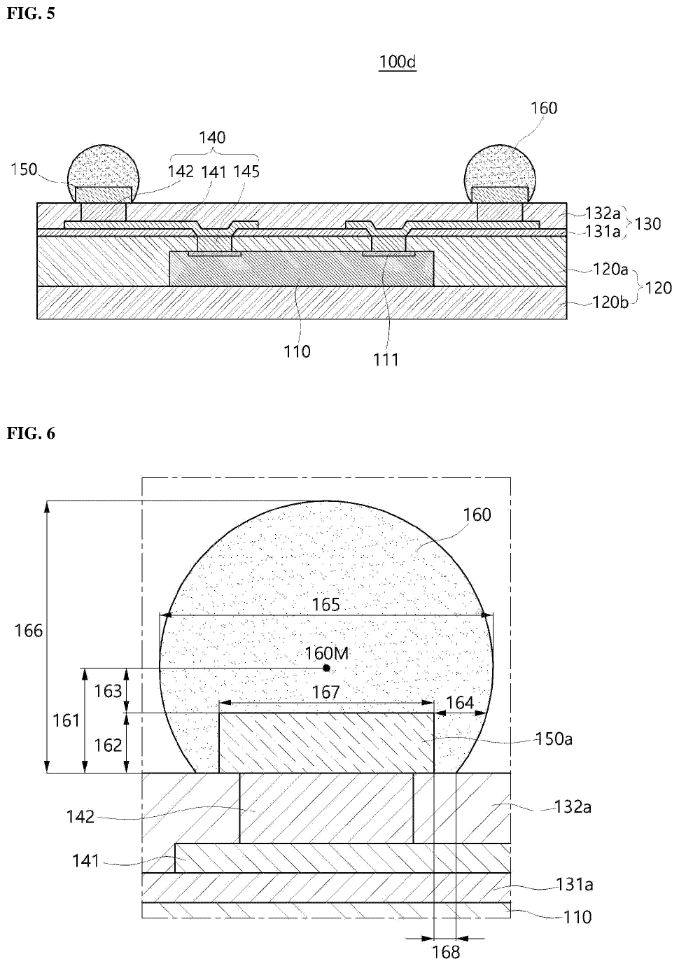

The insulating pattern 130 have a structure including a non-conductive material, and may be provided on the first surface or the protective layer 120 of the semiconductor chip 110, and may surround the periphery of the wiring pattern 140 to prevent an unnecessary electrical short circuit. In particular, in FIGS. 2 to 3, although it is illustrated that the insulating layer 130 is formed directly on the semiconductor chip 110, but it is not limited thereto. That is, the insulating layer 130 may be provided on the protective layer 120 as shown in FIGS. 4 and 5, and in this case, the protective layer 120 may be provided between the semiconductor chip 110 and the insulating layer 130. In addition, the insulating layer 130 may be provided on the first surface and the protective layer 120 of the semiconductor chip 110.

The insulating pattern 130 may have a structure in which a plurality of insulating layers are stacked. That is, in the semiconductor package 100 according to various embodiments of the present invention, the insulating pattern 130 may include a first insulating layer 131 and a second insulating layer 132 which are sequentially stacked. In addition, in the semiconductor package according to various embodiments of the present invention, the insulating pattern 130 may include a plurality of sequentially stacked insulating layers.

At least any one layer of each insulating layer, particularly a layer formed relatively thick (for example, about 20 μm or more or about 30 μm or more) may contribute to improvement of the effective coefficient of thermal expansion of a first structure by its constituent material or its thickness. In this case, the first structure refers to a structure formed by the semiconductor chip 110, the protective layer 120, and the insulating pattern 130, but further include the wiring pattern 140 or may exclude the protective layer 120.

That is, by having a first thickness in a range where at least one of the respective insulating layers is thicker than the other layers, the effective coefficient of thermal expansion of the first structure may be further increased than when the corresponding insulating layer has a thickness smaller than the first thickness. In addition, by including a specific material of the insulating layer, the effective coefficient of thermal expansion of the first structure may be further increased than when the corresponding insulating layer does not include the specific material. However, a detailed description of the increase in the effective coefficient of thermal expansion of the first structure according to the constituent material or thickness of the corresponding insulating layer will be described later.

Each insulating layer may protect the wiring pattern 140 by preventing external physical/chemical damage to the wiring pattern 140, and may function as a buffer against external impact. For example, each insulating layer may be made of an insulating polymer, an epoxy, a silicon oxide film, a silicon nitride film or a combination thereof. Alternatively, each insulating layer may be made of a metal, a non-photosensitive material and/or a photosensitive material, respectively. For example, the insulating polymer may include a general-purpose polymer such as PMMA (Polymethylmethacrylate), PS (Polystyrene), and PBO (Polybenzoxazole), an acrylic based polymer, an imide based polymer, an aryl ether based polymer, an amide based polymer, a fluorine based polymer, a p-xylene based polymer, a vinyl alcohol based polymer, a polymer derivative having a phenolic group, or a combination thereof, and the like.

Each insulating layer may be made of a different material. For example, one insulating layer may be made of a non-photosensitive material, for example, non-photosensitive polyimide, and the other insulating layer may be made of a photosensitive material, for example, photosensitive polyimide. Alternatively, at least two of each insulating layer may be made of the same material. For example, at least two insulating layers may be made of non-photosensitive polyimide, or may be made of photosensitive polyimide.

At least any one layer of each insulating layer, particularly a layer formed relatively thick compared to other layers, may be made of a non-photosensitive material. In this case, a conductive via can be more easily formed in the corresponding insulating layer, particularly in the corresponding thick insulating layer, without a patterning process (increasing manufacturing cost) for the photosensitive material layer through the exposure and development process for the photosensitive material layer. For example, after forming a post through plating, by forming an insulating layer and performing grinding, a conductive via may be formed in the corresponding insulating layer. Accordingly, the insulating layer may be formed thickly, so that it is possible to implement a buffer function and to improve the effective coefficient of thermal expansion of the first structure, which will be described later, and the like, and as well as to reduce manufacturing cost. A layer formed to be relatively thin (e.g., less than about 20 μm in thickness) of each insulating layer may be made of a photosensitive material or a non-photosensitive material.

However, the material of each insulating layer is not limited to the described above, and may be made of more various materials.

The coefficient of thermal expansion (CTE) of each insulating layer may be different from each other, or at least two may be the same. For example, the coefficient of thermal expansion of any one insulating layer may be greater than, less than, or equal to the coefficient of thermal expansion of the other one insulating layer.

At least any one layer of each insulating layer, particularly a layer formed relatively thick compared to other layers, may include a plurality of fillers. In this case, the filler is a particle having a smaller diameter than the thickness of the insulating layer, and increases the coefficient of thermal expansion of the insulating layer, so that the effective coefficient of thermal expansion of the first structure may be improved. That is, the filler may be preferably a material having a coefficient of thermal expansion higher than that of the main insulating material constituting the insulating layer. For example, the filler may have a diameter of about 1/4 or less of the thickness of the insulating layer, and the diameter may be about 5 μm or less, but is not limited thereto. However, when it has a larger diameter than the above limitation, the filler may have a plurality of concave structures in which the surface of the insulating layer is too rough, thereby reducing properties such as surface adhesion of the insulating layer. For example, the filler may include silica (SiO2) and the like, but is not limited thereto.

In addition, when at least any one layer of each insulating layer, particularly a layer formed relatively thick includes the non-photosensitive material and the filler together, the effective coefficient of thermal expansion of the first structure can be improved more effectively.

Surface roughness of each insulating layer in contact with each other may be different from each other. For example, the surface roughness of the upper surface of the other insulating layer in contact with the lower surface of any one insulating layer may be different from the surface roughness of the lower surface of any one insulating layer.

Furthermore, the surface roughness of each insulating layer may be different from each other. For example, the surface roughness of the upper surface of one insulating layer may be greater or smaller than the surface roughness of the upper surface or lower surface of the other insulating layer.

However, the roughness of the upper surface or the lower surface of each insulating layer is not limited to the above-described ones, and may have more various roughness.

Specific shapes, effects, etc. of each insulating layer will be described in more detail according to various embodiments to be described later.

The wiring pattern 140 has a structure including a conductive material, and may transmit an electric signal of the chip terminal 111 or an external device (e.g., a board), etc. in the first direction and the second direction. That is, the wiring pattern 140 may be electrically connected to the chip terminal 111 of the semiconductor chip 110 and may provide an electrical connection path for electrically connecting the chip terminal 111 to an external device. In this case, the wiring pattern 140 may be provided in the insulating pattern 130 and may include various structures depending on the thickness of each insulating layer. That is, the wiring pattern 140 may include a wiring layer 141 capable of transmitting an electric signal in the second direction by extending in the second direction (i.e., horizontal direction) in the insulating pattern 130 toward the outside of the semiconductor chip 110; and a first conductive via 142, a second conductive via 143, and a third conductive via 144 capable of transmitting an electric signal in the first direction by extending in the first direction (i.e., vertical direction) in the insulating pattern 130. Of course, the wiring layer 141 may also include a portion for transmitting an electric signal in the first direction. In addition, each of the conductive vias 142, 143, and 144 may electrically connect the wiring layer 141 and the chip terminal 111, electrically connect one wiring layer 141 and the other wiring layer 141, or electrically connect the wiring layer 141 and the external pad 150.

For example, the wiring pattern 140 may be made of W, Cu, Zr, Ti, Ta, Al, Ru, Pd, Pt, Co, Ni, or a combination thereof. At least two of the wiring layer 141, the first conductive via 142, and the second conductive via 143 may be made of the same material or a combination of the same material. Alternatively, at least two of the wiring layer 141, the first conductive via 142, the second conductive via 143, the third conductive via 144, and a first conductive stud 145 may be made of the same material or a combination of the same material.

In particular, a conductive via (for example, the first conductive via 142) formed on an uppermost layer of an insulating pattern 130, that is, on an uppermost layer of the insulating pattern 130, when the second insulating layer 132, the third insulating layer 133 or the fourth insulating layer 134 is a layer formed relatively thick (for example, about 20 μm or more or about 30 μm or more in thickness), may be formed to protrude from the uppermost layer of the insulating pattern 130.

In addition, a first conductive stud 145 may be further included. As shown in FIG. 5, the first conductive stud 145 may be formed when the wiring pattern 140 and the chip terminal 111 are spaced apart from each other, such as when the protective layer 120 covers the first surface of the semiconductor chip 110. That is, in this case, the first conductive stud 145 may be formed on a portion of the protective layer 120 on the first surface of the semiconductor chip 110 to electrically connect the chip terminal 111 of the semiconductor chip 110 and the remaining wiring layer 141 or the conductive vias 142 and 143. Of course, even if the protective layer 120 does not completely cover the first surface of the semiconductor chip 110, when the wiring pattern 140 and the chip terminal 111 are spaced apart from each other, the first conductive stud 145 may be formed.

Specific shapes, effects, etc. of the wiring layer 141 and the conductive vias 142 and 143 will be described in more detail according to various embodiments to be described later.

The external pad 150 is provided on the insulating pattern 130 and may function as a pad on which the external connection terminal 160 is disposed. That is, the external connection terminal 160 may be disposed on the external pad 150. The external pad 150 may be connected to the wiring pattern 140 through an opening of an uppermost layer of the insulating pattern 130, and may be electrically connected to the chip terminal 111 of the semiconductor chip 110 through the wiring pattern 140. That is, the external pad 150 may be electrically connected to the wiring pattern 140 and the external connection terminal 160, respectively, so that the connection reliability of the external connection terminal 160 can be improved. To this end, the external pad 150 may provide a wetting layer (a cover layer or a preliminary metal layer, etc.) with excellent wettability so that the external connection terminal 160 is well adhered, and may prevent penetration of the external connection terminal 160, and various types of configurations are possible.

For example, the external pad 150 may be an under bump metal layer (UBM), and may include a metal material having excellent conductivity, such as Cu, Al, Cr, W, Ni, Ti, Au, Ag, or a combination thereof, but is not limited thereto.

In addition, the wetting layer may be Au, Pd, Ni, Cu, Sn, or an alloy thereof. Alternatively, it may be Ti, Cr, W, or Al.

The external pad 150 may have a pillar shape 150a with a flat upper portion erected on the uppermost layer of the insulating pattern 130, and may have concave structures 150b, 150c, and 150d in which the central portion of the upper surface thereof is recessed (that is, concave). However, when the uppermost layer of the insulating pattern 130 is a layer formed relatively thick (for example, about 20 μm or more or about 30 μm or more in thickness), without a separate external pad 150, the first conductive via 142 formed to protrude from the uppermost layer of the insulating pattern 130 may replace the external pad 150 to perform the function of the external pad 150 described above or to be described later.

The external connection terminal 160 is a terminal that transmits electric signals from the semiconductor package 100 to an external device, and may be provided on the external pad 150. That is, the external connection terminal 160 may be electrically connected to external pad 150. Accordingly, the external connection terminal 160 may be electrically connected to the chip terminal 111 of the semiconductor chip 110 through the wiring pattern 140, and may be configured to electrically connect the semiconductor package 100 and an external device (for example, board, etc.). That is, the external connection terminal 160 may be a connection terminal for mounting the semiconductor package 100 on a board such as a printed circuit board, which is an external device. However, the external pad 150 may be omitted, and in this case, the external connection terminal 160 may be directly disposed on the wiring pattern 140 exposed through the opening of the uppermost layer of the insulating pattern 130.

For example, the external connection terminal 160 may include a solder bump, and may include Sn, Au, Ag, Ni, In, Bi, Sb, Cu, Zn, Pb, or a combination thereof, but is not limited thereto. In addition, the solder bump may have a ball shape, but is not limited thereto, and may have various shapes such as a cylinder, a polygonal pillar, and a polyhedron.

The external connection terminal 160 may have a shape that completely covers a portion protruding (hereinafter, referred to as “protrusion portion”, the height or thickness of the protrusion portion is referred to as “protrusion height” or “protrusion thickness”, and the width of the protrusion portion is referred to as “protrusion width”) above the upper surface of the uppermost layer of the insulating pattern 130 among the external pad 150 or the first conductive via 142, that is, may be a surface contact type. In this case, the external connection terminal 160 may cover the upper surface and the sidewall of the protrusion portion. In this case, the sidewall of the protrusion portion may refer to a side surface portion of the protrusion portion protruding above the upper surface of the uppermost layer of the insulating pattern 130. For example, during a reflow process for forming the external connection terminal 160, a surface contact type external connection terminal 160 may be formed by proceeding with the reflow process in a state in which a metal material layer having excellent wettability (such as a cover layer or a preliminary metal layer) is formed on the external pad 150 or the first conductive via 142 to enhance the flowability of the external connection terminal 160.

In addition, the surface contact type external connection terminal 160 may be formed to cover a portion of the upper surface of the uppermost layer of the insulating pattern 130 near the protrusion portion, and may form surface contact with the upper surface of the uppermost layer of the insulating pattern 130. For example, the external connection terminal 160 includes a junction interface in contact with the upper surface of the uppermost layer of the insulating pattern 130, and the junction interface of the external connection terminal 160 may have a ring shape continuously extending along the edge of the protrusion portion. The junction interface of the external connection terminal 160 may be formed to have a width (hereinafter, referred to as “junction width”) 168 of at least 5 μm or more in the second direction parallel to the upper surface of the uppermost layer of the insulating pattern 130. For example, the junction width 168 may be about 1 μm to about 20 μm, but is not limited thereto. In addition, on an arbitrary plane including the junction interface between the external connection terminal 160 and the upper surface of the uppermost layer of the insulating pattern 130, when the external pad 150 or the first conductive via 142 protruding above the upper surface of the uppermost layer of the insulating pattern 130 has a width 167 of about 180 μm, the external connection terminal 160 may have a width of about 200 μm.

Referring to FIGS. 2 to 19, the horizontal width 165 of the external connection terminal 160 may be greater than the height 166 of the external connection terminal 160. In this case, the horizontal width 165 of the external connection terminal 160 may mean the maximum value of the width of the external connection terminal 160 in the second direction parallel to the first surface of the semiconductor chip 110, or may mean the distance between two points where the external surface of the external connection terminal 160 meets an arbitrary straight line with respect to the arbitrary straight line crossing the center 160M of the external connection terminal 160 in the second direction. In addition, the height 166 of the external connection terminal 160 may be the height of the external connection terminal 160 in the first direction with respect to the upper surface of the uppermost layer of the insulating pattern 130. The horizontal width 165 of the external connection terminal 160 may be about 1.2 to 1.4 times the height 166 of the external connection terminal 160. For example, the horizontal width 165 of the external connection terminal 160 may be about 210 μm to about 250 μm, but is not limited thereto. In addition, for example, the height 166 of the external connection terminal 160 may be about 165 μm to about 200 μm, but is not limited thereto.

The protrusion height 162 of the protrusion portion may be about 0.09 to about 0.5 times the height 166 of the external connection terminal 160. If the protrusion height 162 is greater than 0.5 times the height 166 of the external connection terminal 160, the sidewall of the protrusion portion may not be covered by the external connection terminal 160, or the thickness of the external connection terminal 160 on the sidewall of the protrusion portion may be formed to be too thin. In addition, if the protrusion height 162 is smaller than 0.09 times the height 166 of the external connection terminal 160, since the external connection terminal 160 has a size larger than necessary compared to the size of the protrusion portion, the height 166 of the external connection terminal 160 may become excessively high, thereby deteriorating the junction reliability between the semiconductor package 100 and the board, and may cause a short between neighboring external connection terminals 160.

The protrusion width 167 may be about 0.6 to about 0.9 times the horizontal width 165 of the external connection terminal 160. If the protrusion width 167 is greater than 0.9 times the horizontal width 165 of the external connection terminal 160, the sidewall of the protrusion portion may not be covered by the external connection terminal 160, or the thickness of the external connection terminal 160 on the sidewall of the protrusion portion may be formed to be too thin. In addition, if the protrusion width 167 is smaller than 0.6 times the horizontal width 165 of the external connection terminal 160, since the external connection terminal 160 has a size larger than necessary compared to the size of the protrusion portion, the height 166 of the external connection terminal 160 may become excessively high, thereby deteriorating the junction reliability between the semiconductor package 100 and the board, and may cause a short between neighboring external connection terminals 160.

On the sidewall of the protrusion portion, the length 164 in the second direction of the external connection terminal 160 may be at least about 1 μm or more. For example, between the top end of the sidewall of the protrusion portion and the outer surface of the external connection terminal 160, the length 164 in the second direction of the external connection terminal 160 may be about 5 μm to about 30 μm, or about 5 μm to about 20 μm, but is not limited thereto.

With respect to one cross-section of the external connection terminal 60 parallel to the first surface of the semiconductor chip 110 and having the largest width in the second direction, if the center of one cross-section of the external connection terminal 160 is defined as the center 160M of the external connection terminal 160, the center 160M of the external connection terminal 160 may be lower than the center of the external connection terminal of a general package. As such, as the center 160M of the external connection terminal 160 is lowered, the external connection terminal 160 may be formed thicker on the sidewall of the external pad 150. For example, between the center 160M of the external connection terminal 160 and the upper surface of the uppermost layer of the insulating pattern 130, if the distance in the first direction is defined as the height 161 of the center 160M of the external connection terminal 160, the height 161 of the center 160M of the external connection terminal 160 may be about 0.4 times or less, or about 0.35 times or less, or 0.3 times or less of the height 166 of the external connection terminal 160. If the height 161 of the center 160M of the external connection terminal 160 is greater than 0.4 times the height 166 of the external connection terminal 160, the sidewall of the protrusion portion may not be covered by the external connection terminal 160, or the thickness of the external connection terminal 160 on the sidewall of the protrusion portion may be formed to be too thin. In addition, the height 161 of the center 160M of the external connection terminal 160 may be about 0.1 times or more, or about 0.15 times or more, or about 0.2 times or more of the height 166 of the external connection terminal 160. If the height 161 of the center 160M of the external connection terminal 160 is less than 0.1 times the height 166 of the external connection terminal 160, the height of the external connection terminal 160 may be too low.

The height 161 of the center 160M of the external connection terminal 160 may be adjusted according to the protrusion height 162, the protrusion width 167, and/or the horizontal width 165 of the external connection terminal 160.

The center 160M of the external connection terminal 160 may be spaced apart from the external pad 150 in the first direction and may be adjacent to the protrusion portion. As the center 160M of the external connection terminal 160 is adjacent to the protrusion portion, the thickness of the external connection terminal 160 covering the sidewall of the protrusion portion may be increased. For example, the shortest distance 163 in the first direction between the center 160M of the external connection terminal 160 and the protrusion portion may be about 0.5 to about 6 times the protrusion height 162. For example, the shortest distance 163 in the first direction of the center 160M of the external connection terminal 160 may be about 10 μm to about 60 μm, but is not limited thereto. That is, the shortest distance 163 in the first direction of the center 160M of the external connection terminal 160 may be equal to the protrusion height 162 or smaller than the protrusion height 162.

In a general semiconductor package, the intermetallic compound formed at the interface between the external pad and the external connection terminal was exposed to the outside, or the external connection terminal covering the intermetallic compound on the sidewall of the external pad was formed with a very thin thickness. There is a problem in that since the intermetallic compound has a property of being brittle to external impact, cracks frequently occur near the edge of the upper surface of the external pad due to external impact, thus deteriorating the junction reliability between the semiconductor package and the board.

However, according to various embodiments of the present invention, since the external connection terminal 160 may completely cover the protrusion portion, it is possible to prevent damage to the protrusion portion due to the external pad 150 being exposed to the outside. In addition, since an external shock may be alleviated by the external connection terminal 160 thickly formed on the sidewall of the protrusion portion, the occurrence of cracks in the vicinity of the protrusion portion may be suppressed, and ultimately, junction reliability between the semiconductor package 100 and an external device such as a board may be improved.

In particular, if the uppermost layer of the insulating layer 130 includes a filler, the surface roughness thereof may be increased according to the uneven concave structure of the filler. Accordingly, the adhesive force between the uppermost layer of the insulating layer 130 and the external pad 150 may be further increased, so that the above-described crack occurrence may be further suppressed. In this case, the filler of the uppermost layer of the insulating layer 130 may directly contact the external pad 150.

The semiconductor package 100 according to various embodiments of the present invention may be a semiconductor package having a fan-in structure or a semiconductor package having a fan-out structure. When the semiconductor package 100 according to various embodiments of the present invention is a semiconductor package having a fan-out structure, the wiring pattern 140 may further extend to the outside of the semiconductor chip 110, and at least one external pad 150 and at least one external connection terminal 160 may be disposed to be spaced apart from the semiconductor chip 110 to the outside.

In the semiconductor package 100 according to various embodiments of the present invention, an electric signal generated from the semiconductor chip 110 may be transmitted to an external device connected to the external connection terminal 160 through the chip terminal 111, the wiring pattern 140, the external pad 150, and the external connection terminal 160 (however, when the first conductive via 142 replaces the external pad 150, the external pad 150 is excluded) in sequence. In addition, an electric signal generated from the external device may be transmitted to the semiconductor chip 110 through the external connection terminal 160, the external pad 150, the wiring pad 140, and the chip terminal 111 (however, when the first conductive via 142 replaces the external pad 150, the external pad 150 is excluded) in sequence. During this electric signal transmission process, the insulating pattern 130 may prevent unnecessary electrical short circuits to the chip terminal 111, the wiring pattern 140, the external pad 150 and the external connection terminal 160 (however, when the first conductive via 142 replaces the external pad 150, the external pad 150 is excluded), and may prevent physical/chemical damage to these components.

<Structure of First Semiconductor Package 100a>

Referring to FIG. 2 and FIG. 6, a first semiconductor package 100a according to an embodiment of the present invention may include a semiconductor chip 110, a protective layer 120, an insulating pattern 130, a wiring pattern 140, an external pad 150, and an external connection terminal 160. However, since the description of the semiconductor chip 110, the protective layer 120, the insulating pattern 130, the wiring pattern 140, the external pad 150, and the external connection terminal 160 is the same as described above, hereinafter, only features of the first semiconductor package 100a that are not described above will be described.

First, the insulating pattern 130 may include a first insulating layer 131a and a second insulating layer 132a stacked on the first insulating layer 131a. In this case, the second insulating layer 132a may have a greater thickness than the first insulating layer 131a. Specifically, the first insulating layer 131a may have a thickness of about 10 μm to about 20 μm, and the second insulating layer 132a may have a thickness of about 20 μm to about 60 μm, or about 30 μm to about 60 μm.

In general, compared to the insulating layer having a thickness of about 5 μm in a conventional semiconductor package, the first insulating layer 131a and the second insulating layer 132a of the semiconductor package 100a according to an embodiment of the present invention may be formed relatively thicker than that, and in particular, the second insulating layer 132a may be formed much thicker than the conventional one. Accordingly, the first insulating layer 131a and the second insulating layer 132a, particularly, the second insulating layer 132a may function as a buffer against external impact, thereby further improving the reliability of the semiconductor package 100a.

In addition, as at least one insulating layer in the insulating pattern 130, that is, the second insulating layer 132a is formed thicker than the conventional insulating layer by about 15 μm to about 55 μm or about 25 μm to about 55 μm, the effective coefficient of thermal expansion of the first structure may naturally increase and approach the effective coefficient of thermal expansion of an external device such as a board on which the semiconductor package 100a is mounted. For example, the effective coefficient of thermal expansion of the first structure of the semiconductor package 100a may be about 9 ppm/° C. to about 17 ppm/° C., but is not limited thereto.

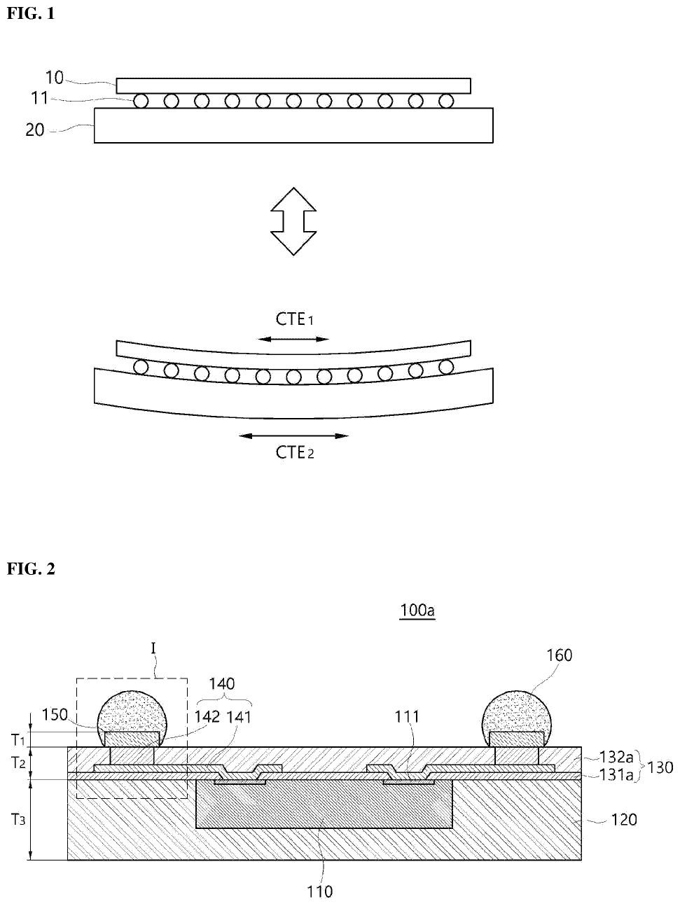

In general, a board such as a PCB has an effective coefficient of thermal expansion of about 15 to 20 ppm/° C., whereas a conventional semiconductor package has an effective coefficient of thermal expansion of less than about 8 ppm/° C. Accordingly, as shown in FIG. 1, due to a sharp difference in thermal expansion (CTE1≠CTE2) occurring between the conventional semiconductor package and the board, a crack could easily occur in an external connection terminal of a conventional semiconductor package. On the other hand, as the effective coefficient of thermal expansion of the first structure of the semiconductor package 100a according to an embodiment of the present invention has a relatively higher value than the conventional one due to an increase in the thickness of the second insulating layer 132a by more than a certain level, it will have a value similar to the value of the effective coefficient of thermal expansion of an external device such as a board. Accordingly, since the first structure of the semiconductor package 100a may thermally expand in a range more similar to that of a board on which the semiconductor package 100a is mounted, upon a sharp difference in thermal expansion, it may reduce cracks that may occur in the external connection terminal 160 of the semiconductor package 100a.

That is, about 20 μm to about 60 μm, or about 30 μm to about 60 μm, the thickness of the second insulating layer 132a, may be an optimal range for similar matching of the buffer function and the effective coefficient of thermal expansion of the first structure to the board. If the second insulating layer 132a is less than 30 μm, particularly less than 20 μm, similar matching of the buffer function and the effective coefficient of thermal expansion may not be possible, and if it is larger than 60 μm, a warpage phenomenon may be induced as stress applied to the semiconductor package 100a is rather increased. However, without limited thereto, the second insulating layer 132a may have various thickness values.

In addition, so that the first structure of the semiconductor package 100a according to an embodiment of the present invention has a value similar to the value of the effective coefficient of thermal expansion of an external device such as a board, the first insulating layer 131a and the second insulating layer 132a, in particular, the second insulating layer 132a formed to be relatively thicker in thickness thereof may preferably have an effective coefficient of thermal expansion of 7 ppm/° C. to 40 ppm/° C. That is, if the effective coefficient of thermal expansion is less than 7 ppm/° C., the effective coefficient of thermal expansion of the first structure of the semiconductor package 100a according to an embodiment of the present invention may be too low, and thus may be out of a similar range with respect to the value of the effective coefficient of thermal expansion of an external device such as a board. In addition, if the effective coefficient of thermal expansion is larger than 40 ppm/° C., the effective coefficient of thermal expansion of the first structure of the semiconductor package 100a according to an embodiment of the present invention may be too large, and thus may be out of a similar range with respect to the value of the effective coefficient of thermal expansion of an external device such as a board.

In particular, if the thickness T3 of the semiconductor chip 110 is reduced, this increases the effective coefficient of thermal expansion of the first structure of the semiconductor package 100a, and thus the effect that the value approaches the value of the effective coefficient of thermal expansion of an external device such as a board on which the semiconductor package 100a is mounted can be doubled. That is, if the thickness T3 of the semiconductor chip 110 is reduced, the insulating pattern 130 has an effect that is relatively thicker, so that the effective coefficient of thermal expansion of the first structure of the semiconductor package 100a can be more easily increased.

To this end, in comparison with a typical conventional semiconductor chip having a thickness greater than 5 times that of the insulating pattern, the thickness T3 of the semiconductor chip 110 of the semiconductor package 100a according to an embodiment of the present invention may be reduced than the conventional one by having about 1.5 to about 10 times, or about 1.5 to about 4 times compared to that of the insulating pattern 130. In addition, in comparison with a typical conventional semiconductor chip having a thickness of 350 μm or more, the thickness T3 of the semiconductor chip 110 of the semiconductor package 100a according to an embodiment of the present invention may be reduced than the conventional one by having about 100 μm to about 300 μm, or 100 μm to about 250 μm, or 100 μm to about 200 μm. If the thickness T3 of the semiconductor chip 110 compared to the insulating pattern 130 is less than 1.5 times or greater than 10 times, a warpage phenomenon may be induced. In particular, if the thickness T3 of the semiconductor chip 110 compared to the insulating pattern 130 is 1.5 times to 4 times, warpage may be further reduced. In addition, if the thickness of the semiconductor chip 110 is less than 100 μm, its mechanical strength is too weak, the semiconductor chip 110 may be easily destroyed during the semiconductor package process, so handling may be difficult, and if it is larger than 250 μm, the effect of increasing the effective coefficient of thermal expansion may be insignificant. However, the thickness of the semiconductor chip 110 is not limited thereto, and may have more various values.

In addition, the wiring pattern 140 may include a wiring layer 141 and a first conductive via 142, but the first conductive via 142 may be omitted if necessary. In this case, the wiring layer 141 may be a trace extending in the second direction on the first insulating layer 131a, and may be electrically connected to the chip terminal 111 of the semiconductor chip 110. The wiring layer 141 may be a single layer or a plurality of layers, and may have a structure in which a plurality of layers spaced apart from each other are connected. For example, the thickness of the wiring layer 141 may be about 5 μm to about 20 μm. The wiring layer 140 may include a tapered shape or a stepped shape, etc. (a portion that transmits an electric signal in the first direction), and in this case, the diameter (length in the second direction) of the region having a small cross-sectional area may be about 5 μm, and the diameter of the region having a large cross-sectional area may be about 15 μm. However, without limited thereto, the wiring layer 141 may have various thickness values according to various shapes.

The first conductive via 142 may be provided on the wiring layer 141, and may extend in the first direction from the second insulating layer 132a and may be electrically connected to the wiring layer 141. That is, the first conductive via 142 may extend in the first direction from the second insulating layer 132a formed thicker than the first insulating layer 131a to the opening on the upper surface of the second insulating layer 132a, and may electrically connect the wiring layer 141 and the external pad 150. For example, the diameter (length in the second direction) of the first conductive via 142 may be about 5 μm to about 20 μm. The first conductive via 142 may include a tapered shape or a stepped shape, etc. and in this case, the diameter of the region having a small cross-sectional area may be about 5 μm, and the diameter of the region having a large cross-sectional area may be about 15 μm. However, without limited thereto, the first conductive via 142 may have various thicknesses and diameters according to various shapes.

The first conductive via 142 may protrude from the upper surface of the second insulating layer 132a. For example, the height that the first conductive via 142 protrudes from the upper surface of the second insulating layer 132a may be about 0.1 μm or more, or about 1 μm or more, or 5 μm, or may be about 20 μm or less, or about 15 μm or less, or about 10 μm or less, but is not limited thereto.

If the first conductive via 142 protrudes from the second insulating layer 132a, the external pad 150 may contact the upper surface and sidewall of the first conductive via 142. The sidewall of the first conductive via 142 may refer to a side surface portion of the first conductive via 142 protruding above the upper surface of the second insulating layer 132a. As such, if the external pad 150 also contacts the sidewall of the first conductive via 142, the contact area between the external pad 150 and the first conductive via 142 may increase, and accordingly, a contact resistance between the external pad 150 and the first conductive via 142 may be reduced.

Meanwhile, the first conductive via 142 may penetrate the wiring layer 141 and contact the upper surface of the first insulating layer 131a. In this case, the wiring layer 141 may have an opening in the upper portion thereof, and a lower portion of the first conductive via 142 may be formed to fill the opening of the wiring layer 141, and a central portion thereof may have a shape protruding downward. The height that the central portion of the lower portion of the first conductive via 142 protrudes downward may correspond to the thickness of the wiring layer 141.

However, if the first conductive via 142 is omitted, the external pad 150 may be directly electrically connected to the wiring layer 141.

In FIG. 2 and FIG. 6, the external pad 150 is shown to have a pillar structure 150a having a flat upper portion, but is not limited thereto, and various modifications are possible.

Meanwhile, the protrusion height 162 of the external pad 150 may be about 20 μm or more to about 50 μm or less, or about 30 μm or more to about 40 μm or less, but is not limited thereto.

In general, in a conventional semiconductor package, compared to the protrusion height of the external pad protruding from the upper surface of the uppermost layer of the insulating pad being 10 μm, the protrusion height 162 of the external pad 150 of the semiconductor package 100a according to an embodiment of the present invention may be formed to be relatively higher than that. Accordingly, the contact resistance of the external pad 150 may be further reduced due to an increase in the contact area with the external connection terminal 160.

In addition, the thickness T1 of the external pad 150 may be about 50 μm, the thickness T2 of the insulating pattern 130 may be about 40 μm, and the thickness T3 of the semiconductor chip 110 may be about 100 μm. That is, the thickness T1 of the external pad with respect to the thickness T2 of the insulating pattern 130 may be about 1 to 1.2 times, and the thickness ratio between a lower structure and an intermediate connection structure may be about 1:0.25 to about 1:0.6. The thickness of a structure formed by the insulating pattern 130 and the external pad 150 (or a structure formed by the insulating pattern 130 and the protrusion portion of the external pad 150) (hereinafter referred to as “second structure”) corresponds to a thickness that disperses stress (hereinafter referred to as “stress dispersion thickness”) applied to the external connection terminal 160 provided between a board, which is an external device on which the semiconductor package 100a is mounted, and the second insulating layer 132a. That is, if the sum of T1 and T2 is less than 80 μm or the thickness ratio between the lower structure and the intermediate connection structure is less than 1:0.25, the effect of dispersing stress may be insignificant, and if the sum of T1 and T2 is greater than 100 μm or the thickness ratio between the lower structure and the intermediate connection structure is greater than 1:0.6, rather, as stress applied to the semiconductor package 100a increases, a warpage phenomenon may be induced. However, without limited thereto, T1, T2, T3, etc. may have various thickness values.

In general, in a conventional semiconductor package, compared to the stress dispersion thickness of the second structure being less than 50 μm, the stress dispersion thickness D1 of the second structure of the semiconductor package 100a according to an embodiment of the present invention may be formed to be relatively thicker than that. Accordingly, the stress applied to the external connection terminal 160 provided between the board on which the semiconductor package 100a is mounted and the second insulating layer 132a can be greatly reduced.

In particular, if the thickness T3 of the semiconductor chip 110 is formed to be about 1.4 times to about 2.5 times the thickness T2 of the insulating pattern 130, the effect of increasing the effective coefficient of thermal expansion and the effect of dispersing stress can be simultaneously realized.

<Structure of Second Semiconductor Package 100b>

Referring to FIG. 3, a second semiconductor package 100b according to an embodiment of the present invention may include a semiconductor chip 110, a protective layer 120, an insulating pattern 130, a wiring pattern 140, an external pad 150, and an external connection terminal 160. However, since the description of the semiconductor chip 110, the protective layer 120, the insulating pattern 130, the wiring pattern 140, the external pad 150, and the external connection terminal 160 is the same as described above, hereinafter, only features of the second semiconductor package 100b that are not described above will be described.

The insulating pattern 130 of the second semiconductor package 100b according to the present embodiment may include a first insulating layer 131a and a second insulating layer 132a stacked on the first insulating layer 131a. In the first semiconductor package 100a according to the above-described embodiment, the first insulating layer 131a of the insulating pattern 120 was formed over the upper surface of the protective layer 120 and the upper surface of the semiconductor chip 110, but the first insulating layer 131a of the second semiconductor package 100b according to the present embodiment is formed on the upper surface of the semiconductor chip 110, and may not be formed on the upper surface of the protective layer 120.

Accordingly, the protective layer 120 may directly contact the wiring layer 141 and the second insulating layer 132a.

<Structure of Third Semiconductor Package 100c>

Referring to FIG. 4, a third semiconductor package 100c according to an embodiment of the present invention may include a semiconductor chip 110, a protective layer 120, an insulating pattern 130, a wiring pattern 140, an external pad 150, and an external connection terminal 160. However, since the description of the semiconductor chip 110, the protective layer 120, the insulating pattern 130, the wiring pattern 140, the external pad 150, and the external connection terminal 160 is the same as in the above-described embodiments, hereinafter, only features of the third semiconductor package 100c that are not described above will be described.

As shown in FIG. 4, the protective layer 120 of the third semiconductor package 100c according to the present embodiment may be formed such that the protective layer 120 covers the first surface of the semiconductor chip 110. That is, the protective layer 120 may be formed to surround the first surface on which the chip terminal 111 of the semiconductor chip 110 is formed, the second surface opposite to the first surface, and the side surface of the semiconductor chip 110.

In addition, the wiring pattern 140 of the third semiconductor package 100c according to the present embodiment may include a wiring layer 141 and a first conductive via 142.

In addition, it may include a first conductive stud 145 for connecting the wiring layer 141 of the wiring pattern 140 and the chip terminal 111.

As shown in FIG. 4, the first conductive stud 145 may be formed if the protective layer 120 covers the first surface of the semiconductor chip 110. That is, in this case, the first conductive stud 145 may be formed to penetrate the protective layer 120 portion on the first surface of the semiconductor chip 110 and contact the chip terminal 111 to electrically connect the chip terminal 111 of the semiconductor chip 110 and the remaining wiring layer 141 or the conductive via 142.

Of course, it is not limited thereto, and even if the protective layer 120 does not cover the first surface of the semiconductor chip 110, when a distance between the wiring pattern 140 and the semiconductor chip 110 is far apart, the first conductive stud 145 may be formed.

<Structure of Fourth Semiconductor Package 100d>

Referring to FIG. 5, a fourth semiconductor package 100d according to an embodiment of the present invention may include a semiconductor chip 110, a protective layer 120, an insulating pattern 130, a wiring pattern 140, an external pad 150, and an external connection terminal 160. However, since the description of the semiconductor chip 110, the protective layer 120, the insulating pattern 130, the wiring pattern 140, the external pad 150, and the external connection terminal 160 is the same as in the above-described embodiments, hereinafter, only features of the fourth semiconductor package 100d that are not described above will be described.

As shown in FIG. 5, the protective layer 120 of the fourth semiconductor package 100d according to the present embodiment is a layer including a non-conductive material, and may be provided on the second surface of the semiconductor chip 110, may be provided to surround the side surface and the second surface of the semiconductor chip 110, or may be provided to surround the side surface, the first surface, and the second surface of the semiconductor chip 110. The protective layer 120 may be a layer to be formed to block the semiconductor chip 110 from a harmful environment. For example, the protective layer 120 may include various oxides or polymer materials, but is not limited thereto. The protective layer 120 may have a thickness of about 15 μm to about 30 μm on the second surface of the semiconductor chip 110. However, the thickness of the protective layer 120 is not limited thereto, and may have more various values. In addition, as shown in FIG. 5, the protective layer 120 may be formed of a plurality of layers 120a and 120b.

In this case, of the protective layer 120, the first protective layer 120a may be formed to cover the entire first surface and the side surface of the semiconductor chip 110, and the second protective layer 120b may be formed to cover and protect only the second surface of the semiconductor chip 110.

Of course, the first protective layer 120a may be formed to cover the first surface and a portion of the side surface of the semiconductor chip 110, and the second protective layer 120b may be formed to cover the second surface and the rest of the side surface of the semiconductor chip 110 that is not covered by the first protective layer 120a.

Alternatively, the first protective layer 120a may be formed to cover the first surface of the semiconductor chip 110, and the second protective layer 120b may be formed to cover the second surface and the entire side surface of the semiconductor chip 110.

Of course, in addition to this, the protective layer 120 may include a third protective layer (not shown) in addition to the first protective layer 120a and the second protective layer 120b.

The first protective layer 120a and the second protective layer 120b may be made of the same material or different materials. For example, the first protective layer 120a may be EMC, and the second protective layer 120b may be a BSP film.

In addition, the wiring pattern 140 of the fourth semiconductor package 100d according to the present embodiment may include a wiring layer 141 and a first conductive via 142.

In addition, it may include a first conductive stud 145 for connecting the wiring layer 141 of the wiring pattern 140 and the chip terminal 111.

As shown in FIG. 5, the first conductive stud 145 may be formed if the protective layer 120 covers the first surface of the semiconductor chip 110. That is, in this case, the first conductive stud 145 may be formed to penetrate the first protective layer 120a portion on the first surface of the semiconductor chip 110 and contact the chip terminal 111 to electrically connect the chip terminal 111 of the semiconductor chip 110 and the remaining wiring layer 141 or the conductive via 142.

Of course, it is not limited thereto, and even if the protective layer 120 does not cover the first surface of the semiconductor chip 110, when a distance between the wiring pattern 140 and the semiconductor chip 110 is far apart, the first conductive stud 145 may be formed.

Meanwhile, the external pad 150 and the wiring pattern 140 may have various structures. Hereinafter, various structures of the external pad 150 and the wiring pattern 140 connected to the external pad 150 will be described.

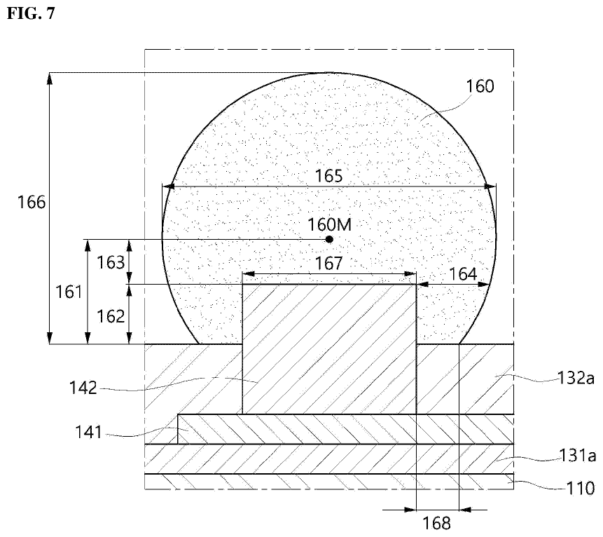

Referring to FIG. 7, the first conductive via 142 may protrude further upward than the second insulating layer 132, which is the uppermost layer of the insulating pattern 130, and may substantially replace the role of the external pad 150. In this case, the external pad 150 may not be provided.

The external connection terminal 160 may have a shape that completely covers a portion protruding above the upper surface of the uppermost layer of the insulating pattern 130 among the external pad 150 or the first conductive via 142, that is, may be a surface contact type. In this case, the external connection terminal 160 may cover the upper surface and the sidewall of the protrusion portion. In this case, the sidewall of the protrusion portion may refer to a side surface portion of the protrusion portion protruding above the upper surface of the uppermost layer of the insulating pattern 130.

For example, during a reflow process for forming the external connection terminal 160, a surface contact type external connection terminal 160 may be formed by proceeding with the reflow process in a state in which a metal material layer having excellent wettability (such as a cover layer or a preliminary metal layer) is formed on the external pad 150 or the first conductive via 142 to enhance the flowability of the external connection terminal 160.

Since the detailed description of the external connection terminal 160 is the same as that described above, a detailed description thereof will be omitted.

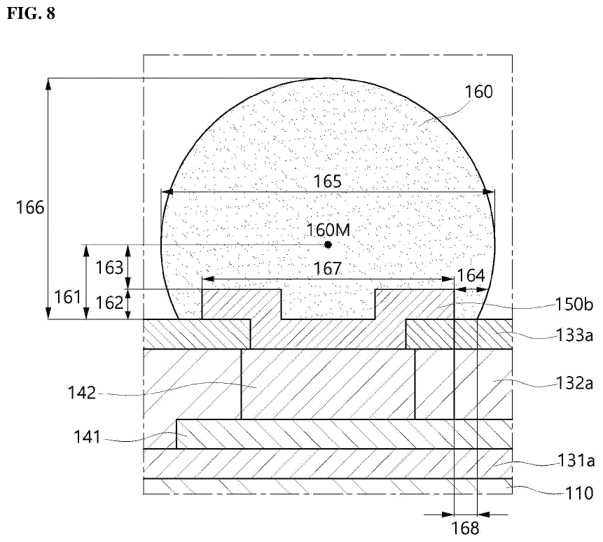

Meanwhile, as shown in FIG. 8, the semiconductor package includes a semiconductor chip 110, a protective layer 120, an insulating pattern 130, a wiring pattern 140, an external pad 150, and an external connection terminal 160, and the insulating pattern 130 may include a first insulating layer 131a, a second insulating layer 132a stacked on the first insulating layer 131a, and a third insulating layer 133a stacked on the second insulating layer 132a.

In this case, the second insulating layer 132a may have a greater thickness than the first insulating layer 131a and the third insulating layer 133a.

In addition, the wiring pattern 140 may include a wiring layer 141 and a first conductive via 142, and the first conductive via 142 may be formed under the opening of the third insulating layer 133a.

In addition, the external pad 150 is shown to have a concave structure 150b, but is not limited thereto, and it may have a pillar structure 150a having a flat upper portion, a first stepped structure having a lower portion protruding toward the third insulating layer 133a, or a second stepped structure in which the first conductive via 142 corresponds to a height 162 protruding from the third insulating layer 133a.

In addition, the external pad 150 may be formed on the opening of the third insulating layer 133a, it may be formed up to the inside of the opening of the third insulating layer 133a to protrude above the opening of the third insulating layer 133a, and it may contact the upper surface of the third insulating layer 133a.

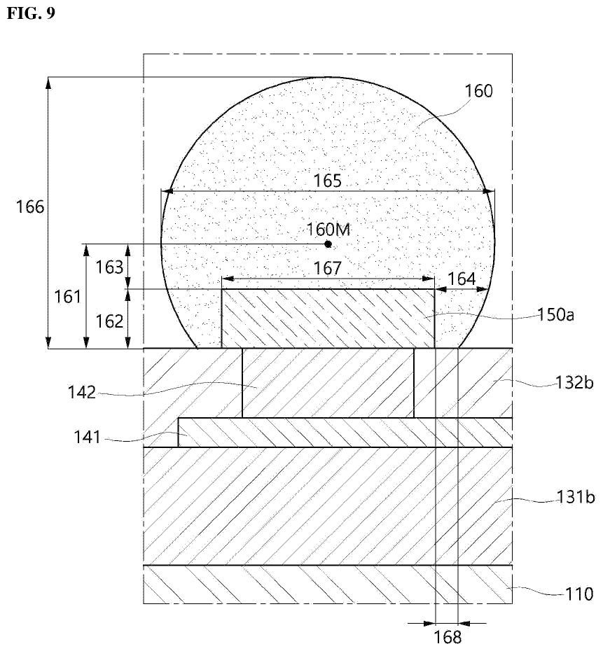

Meanwhile, as shown in FIG. 9, the insulating pattern 130 of the semiconductor package may include a first insulating layer 131b and a second insulating layer 132b stacked on the first insulating layer 131b. In this case, the first insulating layer 131b and the second insulating layer 132b have the same or different thicknesses, but have a thickness greater than or equal to a predetermined thickness. Specifically, the first insulating layer 131b and the second insulating layer 132b may be about 20 μm to about 60 μm, or about 30 μm to about 60 μm. In particular, at least one of the first insulating layer 131b and the second insulating layer 132b may be about 30 μm or more, and the total thickness thereof may be about 50 μm to about 110 μm.

In general, compared to the insulating layer having a thickness of about 5 μm in a conventional semiconductor package, the first insulating layer 131b and the second insulating layer 132b of the semiconductor package 100d according to an embodiment of the present invention may be formed relatively thicker than that. Accordingly, the first insulating layer 131b and the second insulating layer 132b, particularly, the second insulating layer 132b may function as a buffer against external impact, thereby further improving the reliability of the semiconductor package 100.

In addition, since other portions of the insulating pattern 130 are the same as in the above-described embodiment, detailed descriptions thereof will be omitted.

In this case, the structure of the wiring layer 141 and the first conductive via 142 of the wiring pattern 140, the external pad 150 and the external connection terminal 160 is substantially the same as the example described with reference to FIG. 6 as an example, so a detailed description will be omitted.

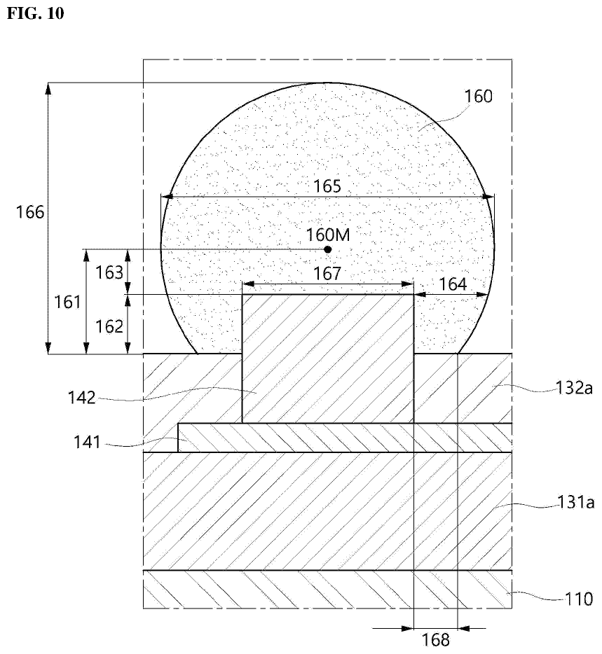

Meanwhile, as shown in FIG. 10, the first conductive via 142 of the semiconductor package may be formed to protrude from the second insulating layer 132b in the first direction to be electrically connected to the wiring layer 141. That is, the first conductive via 142 is formed to protrude from the opening of the upper surface of the second insulating layer 132b, and may electrically connect the wiring layer 141 and the external connection terminal 160. For example, the diameter (length in the second direction) of the first conductive via 142 may be about 5 μm to about 20 μm. The first conductive via 142 may include a tapered shape or a stepped shape, etc. and in this case, the diameter of the region having a small cross-sectional area may be about 5 μm, and the diameter of the region having a large cross-sectional area may be about 15 μm. However, without limited thereto, the first conductive via 142 may have various thicknesses and diameters according to various shapes.

In FIG. 10, the first conductive via 142 is shown to have a pillar structure having a flat upper portion, but is not limited thereto, and may have a concave structure or the like in which the upper portion is concave.

Meanwhile, the protrusion height 162 of the first conductive via 142 may be about 20 μm or more to about 50 μm or less, or about 30 μm or more to about 40 μm or less, but is not limited thereto.

In general, in a conventional semiconductor package, compared to the protrusion height of the external pad protruding from the upper surface of the uppermost layer of the insulating pad being 10 μm, the protrusion height 162 of the first conductive via 142 replacing the external pad 150 of the semiconductor package 100 according to an embodiment of the present invention may be formed to be relatively higher than that. Accordingly, the contact resistance of the first conductive via 142 may be further reduced due to an increase in the contact area with the external connection terminal 160.

The thickness D1 of a second structure formed by the insulating pattern 130 and the first conductive via 142 (or a second structure formed by the insulating pattern 130 and the protrusion portion of the first conductive via 142) corresponds to a thickness that disperses stress applied to the external connection terminal 160 provided between a board on which the semiconductor package 100 is mounted and the second insulating layer 132a. The stress dispersion thickness D1 of the second structure in the semiconductor package 100 may be about 60 μm or more or about 70 μm or more, and may be about 100 μm or less or about 110 μm or less. If D1 is less than 60 μm, the effect of dispersing stress may be insignificant, and if D1 is greater than 110 μm, rather, as stress applied to the semiconductor package increases, a warpage phenomenon may be induced. However, without limited thereto, D1 may have various thickness values.

In general, in a conventional semiconductor package, compared to the stress dispersion thickness of the second structure being less than 50 μm, the stress dispersion thickness D1 of the second structure of the semiconductor package according to an embodiment of the present invention may be formed to be relatively thicker than that. Accordingly, the stress applied to the external connection terminal 160 provided between the board on which the semiconductor package is mounted and the second insulating layer 132a can be greatly reduced.

Meanwhile, descriptions of configurations and effects of the insulating pattern 130, the effective coefficient of thermal expansion of the first structure, the wiring layer 141, the second conductive via 143, the thickness T3 of the semiconductor chip 110, and the ratio of T2 and T3, etc. may be the same as the description of the structure of the first semiconductor package 100a and the description of the structure of FIG. 7.

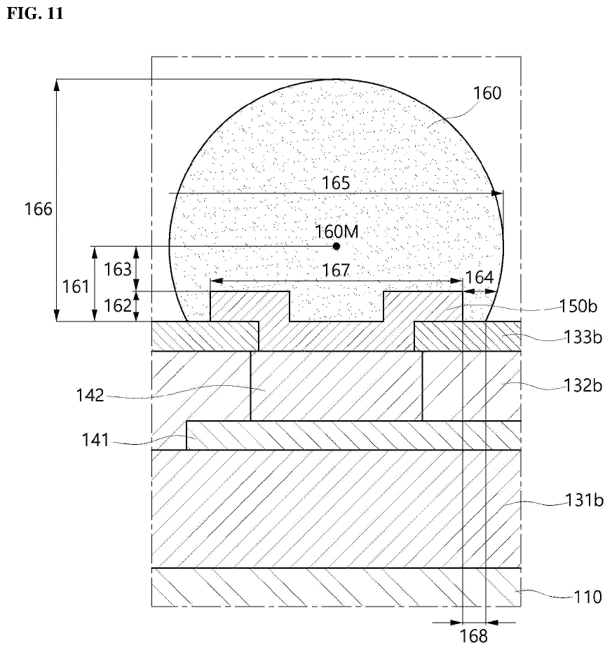

In addition, as shown in FIG. 11, the insulating pattern 130 of the semiconductor package may include a first insulating layer 131b, a second insulating layer 132b stacked on the first insulating layer 131b, and a third insulating layer 133b stacked on the second insulating layer 132b. In this case, the first insulating layer 131b and the second insulating layer 132b may have a greater thickness than the third insulating layer 133b. Specifically, the thickness of the third insulating layer 133b may be about 10 μm to about 20 μm. In addition, the thickness or the like of the first insulating layer 131b and the second insulating layer 132b may be the same as described with reference to FIG. 9.

Meanwhile, at least one of the first insulating layer 131b and the second insulating layer 132b may be made of a non-photosensitive material, or the insulating layers 131, 132, and 133 may include 5 to 30 wt % of a metal, 1 to 20 wt % of a photosensitive material, and the remaining amount of a non-photosensitive material. In this case, at least one of the first conductive via 142 and the first conductive stud 145 may be formed in the first insulating layer 131b or the second insulating layer 132b, without a patterning process (increasing manufacturing cost) for the photosensitive material layer through the exposure and development process for the photosensitive material layer. Accordingly, thicker formation (about 20 μm to about 60 μm, or about 30 μm to about 60 μm, etc.) of the first insulating layer 131b or the second insulating layer 132b is possible, and thus it is possible to implement a buffer function and to improve the effective coefficient of thermal expansion, which is described above, and the like, and as well as to reduce manufacturing cost.

In addition, since other portions of the insulating pattern 130 are the same as in the above-described embodiment, detailed descriptions thereof will be omitted.

In addition, the wiring pattern 140 may include a wiring layer 141 and a first conductive via 142, and their configuration may be the same as described above in the structure of the fourth semiconductor package 100d. However, the first conductive via 142 may be formed under the opening of the third insulating layer 133b, or may protrude above the opening of the third insulating layer 133b, or may be formed within the opening of the third insulating layer 133b without protruding above the opening of the third insulating layer 133b.

In addition, the first conductive studs 145 may be formed to penetrate the first insulating layer 131b.

In addition, the external pad 150 is shown to have a concave structure 150b, but is not limited thereto, and it may have a pillar structure 150a having a flat upper portion, a first stepped structure having a lower portion protruding toward the third insulating layer 133b, or a second stepped structure in which the first conductive via 142 corresponds to a height 162 protruding from the third insulating layer 133b. Descriptions of these structures and effects may be the same as those described above, except for a point that symbols are changed in the description of the structure of the first semiconductor package 100a. However, the external pad 150 may be formed on the opening of the third insulating layer 133b, it may be formed up to the inside of the opening of the third insulating layer 133b to protrude above the opening of the third insulating layer 133b, and it may contact the upper surface of the third insulating layer 133b.

Meanwhile, descriptions of configurations and effects of the protrusion height T1 of the external pad 150, the thickness T2 of the insulating pattern 130, the thickness T3 of the semiconductor chip 110, and the ratio of T2 and T3, etc. may be the same as the description of the structure of the first semiconductor package 100a and the description of the structure of FIG. 8.

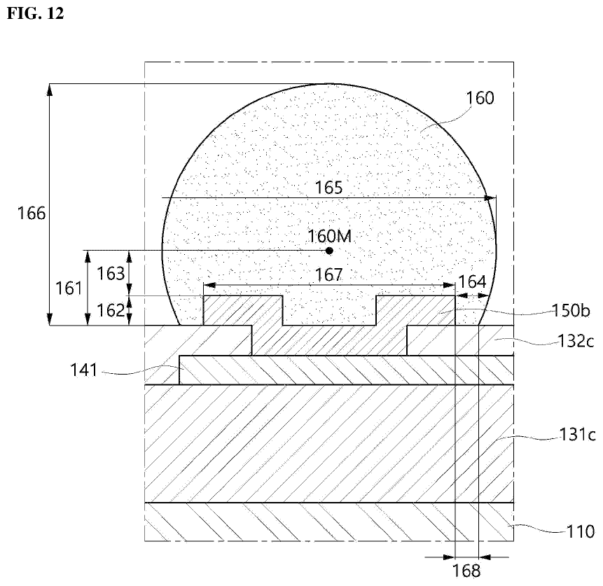

Meanwhile, as shown in FIG. 12, the semiconductor package may include a semiconductor chip 110, a protective layer 120, an insulating pattern 130, a wiring pattern 140, an external pad 150, and an external connection terminal 160.

First, the insulating pattern 130 may include a first insulating layer 131c and a second insulating layer 132c stacked on the first insulating layer 131c. In this case, the first insulating layer 131c may have a greater thickness than the second insulating layer 132c. Specifically, the first insulating layer 131c may be about 20 μm to about 60 μm, or about 30 μm to about 60 μm, and the thickness of the second insulating layer 132c may be about 10 μm to about 20 μm.

In general, compared to the insulating layer having a thickness of about 5 μm in a conventional semiconductor package, the first insulating layer 131c and the second insulating layer 132c of the semiconductor package according to an embodiment of the present invention may be formed relatively thicker than that, and in particular, the first insulating layer 131c may be formed much thicker than the conventional one. Accordingly, the first insulating layer 131c and the second insulating layer 132c, particularly, the first insulating layer 131c may function as a buffer against external impact, thereby further improving the reliability of the semiconductor package.

In addition, as at least one insulating layer in the insulating pattern 130, that is, the first insulating layer 131c is formed thicker than the conventional insulating layer by about 15 μm to about 55 μm or about 25 μm to about 55 μm, the effective coefficient of thermal expansion of the first structure in the semiconductor package may naturally increase and approach the effective coefficient of thermal expansion of an external device such as a board on which the semiconductor package is mounted. For example, the effective coefficient of thermal expansion of the first structure of the semiconductor package may be about 9 ppm/° C. to about 17 ppm/° C., but is not limited thereto.

That is, about 20 μm to about 60 μm, or about 30 μm to about 60 μm, the thickness of the first insulating layer 131c, may be an optimal range for similar matching of the buffer function and the effective coefficient of thermal expansion of the first structure to the board. If the first insulating layer 131c is less than 30 μm, particularly less than 20 μm, similar matching of the buffer function and the effective coefficient of thermal expansion may not be possible, and if it is larger than 60 μm, a warpage phenomenon may be induced as stress applied to the semiconductor package is rather increased. However, without limited thereto, the first insulating layer 131c may have various thickness values.

In addition, so that the first structure of the semiconductor package according to an embodiment of the present invention has a value similar to the value of the effective coefficient of thermal expansion of an external device such as a board, the first insulating layer 131c and the second insulating layer 132c, in particular, the first insulating layer 131c formed to be relatively thicker in thickness thereof may preferably have an effective coefficient of thermal expansion of 7 ppm/° C. to 40 ppm/° C. That is, if the effective coefficient of thermal expansion is less than 7 ppm/° C., the effective coefficient of thermal expansion of the first structure of the semiconductor package according to an embodiment of the present invention may be too low, and thus may be out of a similar range with respect to the value of the effective coefficient of thermal expansion of an external device such as a board. In addition, if the effective coefficient of thermal expansion is larger than 40 ppm/° C., the effective coefficient of thermal expansion of the first structure of the semiconductor package according to an embodiment of the present invention may be too large, and thus may be out of a similar range with respect to the value of the effective coefficient of thermal expansion of an external device such as a board.

In addition, the wiring pattern 140 may include a wiring layer 141. In addition, the external pad 150 may be disposed to directly contact the wiring layer 141. That is, the external pad 150 may directly contact the wiring layer 141 without a separate conductive via 142.

In FIG. 12, the external pad 150 is illustrated as having a concave structure 150b, but is not limited thereto, and it may have a pillar structure 150a having a flat upper portion, or a first stepped structure having a lower portion protruding toward the second insulating layer 132d.

The thickness 162 of the external pad 150 may be about 20 μm or more to about 50 μm or less, or about 30 μm or more to about 40 μm or less. However, it is not limited thereto, and may be formed thicker than this if necessary.

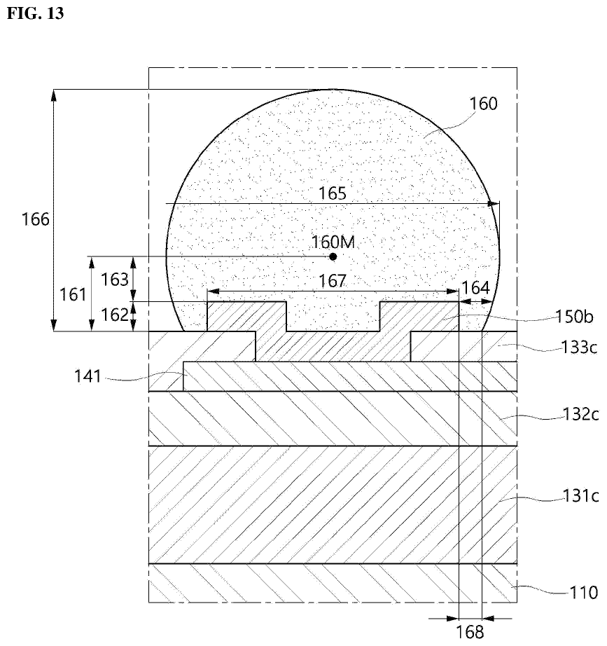

Meanwhile, as shown in FIG. 13, the semiconductor package may include a semiconductor chip 110, a protective layer 120, an insulating pattern 130, a wiring pattern 140, an external pad 150, and an external connection terminal 160. However, since the description of the semiconductor chip 110, the protective layer 120, the insulating pattern 130, the wiring pattern 140, the external pad 150, and the external connection terminal 160 is the same as described above with reference to FIG. 12, hereinafter, only features different from the semiconductor package of FIG. 12 will be described.

First, the insulating pattern 130 may include a first insulating layer 131c, a second insulating layer 132c stacked on the first insulating layer 131c, and a third insulating layer 133c stacked on the second insulating layer 132c. In this case, the first insulating layer 131c may have a greater thickness than the second insulating layer 132c and the third insulating layer 133c. Specifically, the thickness of the third insulating layer 133c may be about 10 μm to about 20 μm. In addition, the thickness or the like of the first insulating layer 131c and the second insulating layer 132c is the same as described with reference to FIG. 12.

In addition, the wiring pattern 140 may include a wiring layer 141, and the external pad 150 may be disposed to directly contact the wiring layer 141.

In FIG. 13, the external pad 150 is illustrated as having a concave structure 150b, but is not limited thereto, and it may have a pillar structure 150a having a flat upper portion, or a first stepped structure having a lower portion protruding toward the third insulating layer 133c. However, the external pad 150 may be formed on the opening of the third insulating layer 133c, it may be formed up to the inside of the opening of the third insulating layer 133c to protrude above the opening of the third insulating layer 133c, and it may contact the upper surface of the third insulating layer 133c.

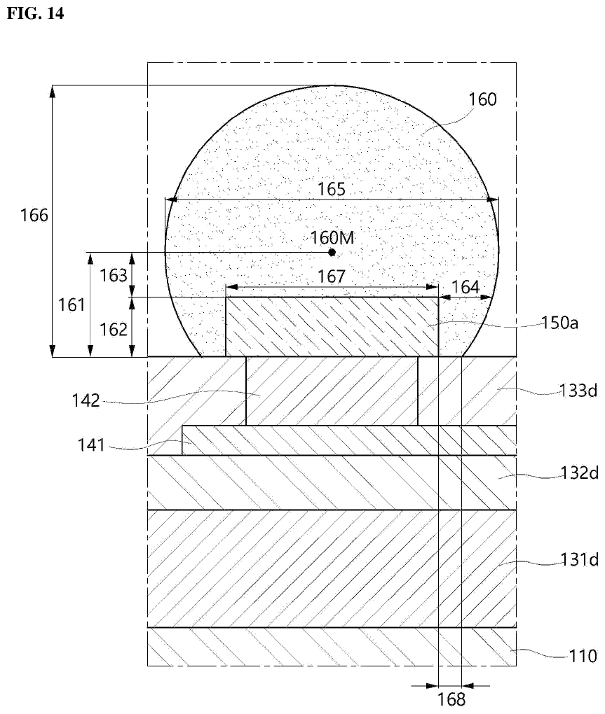

Meanwhile, as shown in FIG. 14, the semiconductor package may include a semiconductor chip 110, a protective layer 120, an insulating pattern 130, a wiring pattern 140, an external pad 150, and an external connection terminal 160.

First, the insulating pattern 130 may include a first insulating layer 131d, a second insulating layer 132d stacked on the first insulating layer 131d, and a third insulating layer 133d stacked on the second insulating layer 132d. In this case, the first insulating layer 131d and the third insulating layer 133d may have a greater thickness than the second insulating layer 132d. Specifically, the first insulating layer 131d and the third insulating layer 133d may be about 20 μm to about 60 μm, or about 30 μm to about 60 μm, and the thickness of the second insulating layer 132d may be about 10 μm to about 20 μm.

In general, compared to the insulating layer having a thickness of about 5 μm in a conventional semiconductor package, the first insulating layer 131d, the second insulating layer 132d, and the third insulating layer 133d of the semiconductor package according to an embodiment of the present invention may be formed relatively thicker than that, and in particular, the first insulating layer 131d and the third insulating layer 133d may be formed much thicker than the conventional one. Accordingly, the first insulating layer 131d, the second insulating layer 132d, and the third insulating layer 133d, particularly, the first insulating layer 131d and the third insulating layer 133d may function as a buffer against external impact, thereby further improving the reliability of the semiconductor package.

In addition, the wiring pattern 140 may include a wiring layer 141 and a first conductive via 142.

The first conductive via 142 may be provided on the wiring layer 141, and may extend in the first direction from the third insulating layer 133d and may be electrically connected to the wiring layer 141. That is, the first conductive via 142 may extend in the first direction from the third insulating layer 133d formed thicker than the second insulating layer 132d to the opening on the upper surface of the third insulating layer 133d, and may electrically connect the wiring layer 141 and the external pad 150. For example, the diameter (length in the second direction) of the first conductive via 142 may be about 5 μm to about 20 μm. The first conductive via 142 may include a tapered shape or a stepped shape, etc. and in this case, the diameter of the region having a small cross-sectional area may be about 5 μm, and the diameter of the region having a large cross-sectional area may be about 15 μm. However, without limited thereto, the first conductive via 142 may have various thicknesses and diameters according to various shapes.

The first conductive via 142 may protrude from the upper surface of the third insulating layer 133d. For example, the height that the first conductive via 142 protrudes from the upper surface of the third insulating layer 133d may be about 0.1 μm or more, or about 1 μm or more, or 5 μm, or may be about 20 μm or less, or about 15 μm or less, or about 10 μm or less, but is not limited thereto.

If the first conductive via 142 protrudes from the third insulating layer 133d, the external pad 150 may contact the upper surface and sidewall of the first conductive via 142.

However, if the first conductive via 142 is omitted, the external pad 150 may be directly electrically connected to the wiring layer 141.

In FIG. 14, the external pad 150 is shown to have a structure 150a having a flat upper portion, but is not limited thereto, and it may have a first stepped structure having a lower portion protruding toward the second insulating layer 132a, a concave structure 150b, 150c, and 150d in which an upper portion is concave, or a second stepped structure in which the first conductive via 142 corresponds to a height protruding from the second insulating layer 132a.

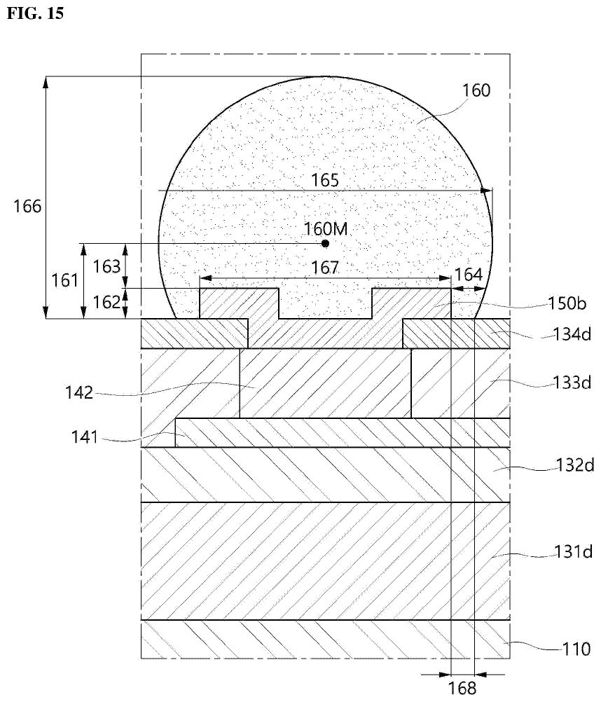

Meanwhile, as shown in FIG. 15, the semiconductor package may include a semiconductor chip 110, a protective layer 120, an insulating pattern 130, a wiring pattern 140, an external pad 150, and an external connection terminal 160.

First, the insulating pattern 130 may include a first insulating layer 131d, a second insulating layer 132d stacked on the first insulating layer 131d, a third insulating layer 133d stacked on the second insulating layer 132d, and a fourth insulating layer 134d stacked on the third insulating layer 133d. In this case, the first insulating layer 131d and the third insulating layer 133d may have a greater thickness than the second insulating layer 132d and the fourth insulating layer 134d. Specifically, the thickness of the fourth insulating layer 133d may be about 10 μm to about 20 μm. In addition, the thickness of the first insulating layer 131d, the second insulating layer 132d, and the third insulating layer 133d may be the same as described with reference to FIG. 14.

In addition, the wiring pattern 140 may include a wiring layer 141 and a first conductive via 142. However, the first conductive via 142 may be formed under the opening of the fourth insulating layer 134d, or may protrude above the opening of the fourth insulating layer 134d, or may be formed within the opening of the fourth insulating layer 134d without protruding above the opening of the fourth insulating layer 134d.

In FIG. 15, the external pad 150 is shown to have a concave structure 150b, but is not limited thereto, and it may have a pillar structure 150a having a flat upper portion, a first stepped structure having a lower portion protruding toward the fourth insulating layer 134d, or a second stepped structure in which the first conductive via 142 corresponds to a height 162 protruding from the fourth insulating layer 134d. However, the external pad 150 may be formed on the opening of the fourth insulating layer 134d, it may be formed up to the inside of the opening of the fourth insulating layer 134d to protrude above the opening of the fourth insulating layer 134d, and it may contact the upper surface of the fourth insulating layer 134d.

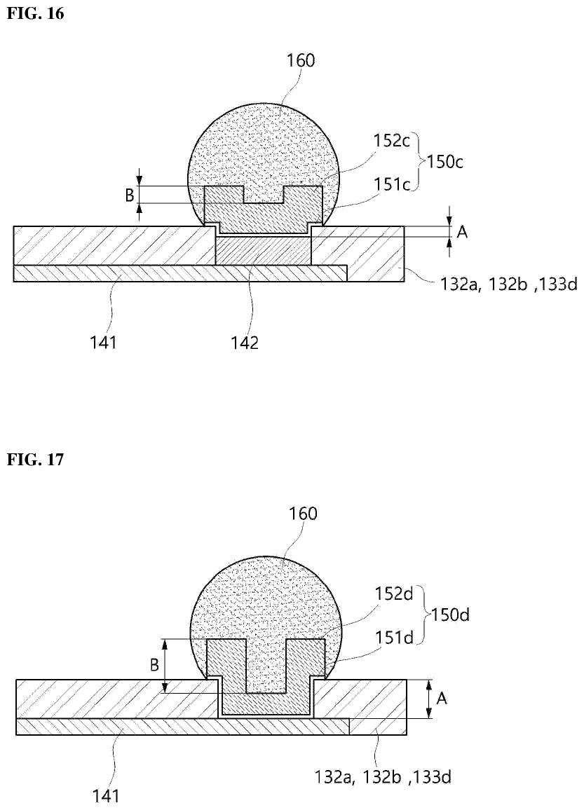

Meanwhile, FIGS. 16 and 17 are cross-sectional views showing enlarged periphery of external pads 150c and 150d having various concave structures.

In addition, as shown in FIG. 16 and FIG. 17, the external pad 150 may have a structure in which a plurality of layers are stacked. For example, the external pad 150 may include a lower metal layer 151 and an upper metal layer 152 on the lower metal layer 151.

The lower metal layer 151 may be formed on the wiring pattern 140 exposed through the opening of the uppermost layer of the insulating pattern 130, and may extend along the surface of the uppermost layer of the insulating pattern 130. For example, the lower metal layer 151 may be a seed layer or an adhesive layer for forming the upper metal layer 152, and may include Ti, Cu, Cr, W, Ni, Al, Pd, Au, or a combination thereof, but is not limited thereto.

The lower metal layer 151 may be a single metal layer, but is not limited thereto, and may have a multilayer structure including a plurality of metal layers. For example, the lower metal layer 151 may include a first sub metal layer and a second sub metal layer sequentially stacked on the uppermost layer of the insulating pattern 130 and the wiring pattern 140. The first sub metal layer may include a metal material having excellent adhesion properties to the uppermost layer of the insulating pattern 130. For example, the first sub metal layer may include Ti, but is not limited thereto. The second sub metal layer may function as a seed layer for forming the upper metal layer. For example, the second sub metal layer may include Cu, but is not limited thereto.

The upper metal layer 152 may be provided on the lower metal layer 151. For example, the upper metal layer 152 may be formed by a plating method using the lower metal layer 151 as a seed. The upper metal layer 152 may have a pillar shape erected on the uppermost layer of the insulating pattern 130, and may have a concave structure in which the central portion of the upper surface is depressed. If the upper metal layer 152 has a concave structure, the lower metal layer 151 may have a correspondingly stepped structure. For example, the upper metal layer 152 may include Cu or a Cu alloy, but is not limited thereto.

In addition, as shown in FIG. 16 and FIG. 17, the external pad 150 may have a first stepped structure having a lower portion protruding toward the uppermost layer of the insulating pattern 130, a concave structure 150c and 150d in which an upper portion is concave, or a second stepped structure in which the first conductive via 142 corresponds to a height protruding from the second insulating layer 132a. In this case, the external pad 150 may have a structure in which two or more structures among the pillar structure, the first stepped structure, the concave structure, and the second stepped structure are combined. In addition, the external pad 150 may include a lower metal layer 151 and an upper metal layer 152 on the lower metal layer 151.

Meanwhile, each of the concave structures 150c and 150d of the external pad 150 may be divided according to a height at which the lower surface of the external pad 150 is located. That is, a first concave structure 150b shown in FIG. 11 is a structure provided when the position of the lower surface of the external pad 150 coincides with the position of the upper surface of the uppermost layer of the insulating pattern 130. In addition, as shown in FIG. 16 and FIG. 17, a second concave structure 150c and a third concave structure 150d are structures provided when the position of the lower surface of the external pad 150 is lower than the position of the upper surface of the uppermost layer of the insulating pattern 130, that is, when the lower surface of the external pad 150 is located in the uppermost layer of the insulating pattern 130. However, the second concave structure 150c may be provided on the first conductive via 142, whereas the third concave structure 150d may be provided on the wiring layer 141 while the first conductive via 142 is omitted.

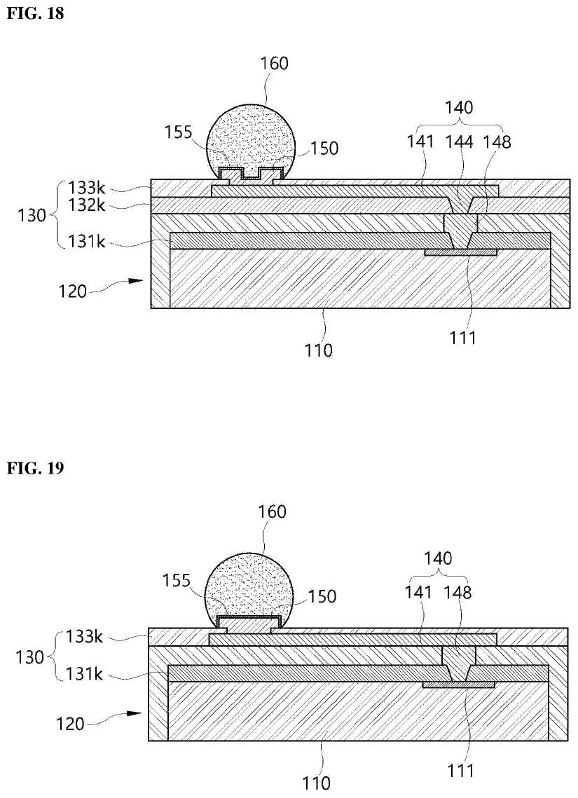

Meanwhile, as shown in FIG. 18, the semiconductor package may include a semiconductor chip 110, a protective layer 120, an insulating pattern 130, a wiring pattern 140, an external pad 150, and an external connection terminal 160. However, since the description of the semiconductor chip 110, the protective layer 120, the insulating pattern 130, the wiring pattern 140, the external pad 150, and the external connection terminal 160 is the same as described above, hereinafter, only features of the 11th semiconductor package that are not described above, that is, features different from the 10th semiconductor package 100j will be described.

A protective film 131k may be formed on the first surface of the semiconductor chip 100. A portion of the protective film 131k in which the chip pad 111 is formed may be opened. Of course, the protective film 131k may be omitted if necessary.

The protective layer 120 may be formed to cover the first surface of the semiconductor chip 110, and the insulating pattern 130 may be formed on one surface of the protective layer 120 covering the first surface of the semiconductor chip 110.

In this case, the protective layer 120 may be formed to surround the first surface and the side surface of the semiconductor chip 110. The protective layer 120 may cover the second surface of the semiconductor chip 110, or may not cover the second surface of the semiconductor chip 110, if necessary.

The insulating pattern 130 may include a second insulating layer 132k formed at an upper side of the protective layer, and a third insulating layer 133k provided at an upper side of the second insulating layer.

The first insulating layer 131k may be opened to expose the chip pad 111, and the protective layer 120 and the second insulating layer 132k may also be opened for electrical connection between the chip pad and a redistribution layer 141.

In order to electrically connect the redistribution layer 141 and the chip pad 111, a second conductive stud 148 may be formed between the redistribution layer 141 and the chip pad 111.

The second conductive stud 148 may extend in a height direction of the semiconductor package and may be formed of a conductive material such as copper to electrically connect the redistribution layer 141 and the chip pad 111.

In addition, since the second conductive stud 148 is formed in the height direction, the thickness of the protective layer 120 or the insulating pattern 130 surrounding the semiconductor chip 110 may be formed thicker, whereby the protective effect of the semiconductor chip 110 may be further increased.

In addition, the redistribution layer 141 may be positioned between the second insulating layer 132k and the third insulating layer 133k. And, a portion of the third insulating layer 133k may be opened to position the external pad 150, and an external connection terminal 160 may be provided at an upper side of the external pad 150.

The wiring pattern 140 may include a wiring layer 141 and a first conductive via 144.

Also, a second conductive stud 148 may be formed between the protective film 131k and the conductive via 144.

If the second insulating layer 132k is formed under the wiring pattern 140, a conductive via 144 may be further formed between the wiring layer 141 and the second conductive stud 148 by extending in the vertical direction by the thickness of the second insulating layer 132k.

That is, the conductive via 144 may be formed to penetrate the second insulating layer 132k, and the second conductive stud 148 may be formed to pass through the protective layer 120 and the protective film 131k formed on the first surface of the semiconductor chip 110 to be electrically connected to the chip pad 111.

Of course, as shown in FIG. 19, the second insulating layer 132k may be deleted if necessary. As shown in FIG. 19, if the second insulating layer 132k is deleted, the redistribution layer 141 may directly contact the second conductive stud 148, and in this case, the conductive via 144 may be deleted.

Meanwhile, at least a portion of one surface and a side surface of the external pad 150 is exposed to the upper side of the insulating pattern 130, and the external connection terminal 160 provided on the external pad 150 may be formed by collapsing so as to be in contact with one surface and a side surface of the external pad 150 facing toward the upper side of the semiconductor package.

That is, the external connection terminal 160 provided on the external pad 150 may be formed to contact one surface and a side surface of the external pad 150.

In this case, on the surface of the external pad 150 in contact with the external connection terminal 160, a wetting layer 155 (a cover layer or a preliminary metal layer, etc.) having excellent wettability may be formed so that the external connection terminal 160 is well adhered.

In this case, the wetting layer 155 may be formed of gold (Au) or an alloy component including gold by an electroless gold plating method. Alternatively, the wetting layer 155 may be Au, Pd, Ni, Cu, Sn, or an alloy thereof. Alternatively, it may be made of Ti, Cr, W, or Al.

In this case, a portion of the external pad 150 protruding upward than the insulating pattern 140 may be formed to have a thickness of 30 μm or more.

The external pad 150 may be formed so that one surface thereof is flat or has a concave structure. In addition, a lower portion of the external pad 150 may be formed to have a protruding structure protruding toward the redistribution layer 141.

Meanwhile, descriptions of configurations and effects of the protrusion height Ti of the external pad 150, the thickness T2 of the insulating pattern 130, the thickness T3 of the semiconductor chip 110, and the ratio of T2 and T3, etc. may be the same as those described above, except for a point that symbols are changed in the structure of the first semiconductor package 100a.

Hereinafter, a method for manufacturing the above-described semiconductor package will be described.

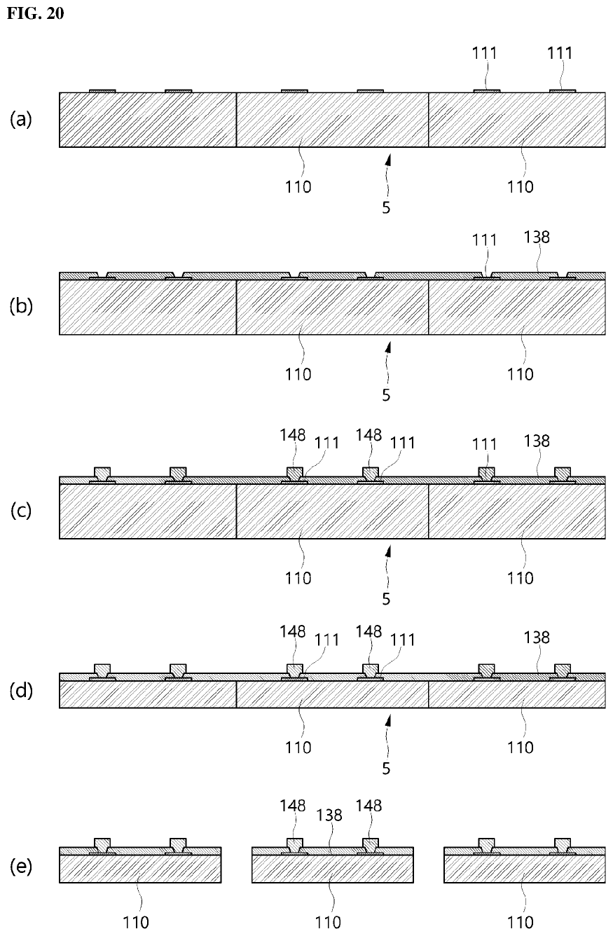

(a) to (e) in FIG. 20 are views showing from formation of a second conductive stud 148 on a wafer in a state before being cut into semiconductor chips 110 to cutting them into individual semiconductor chips 110.

First, as shown in FIG. 20(a), a wafer 5 before a plurality of semiconductor chips 110 are cut is prepared. One or more chip pads 111 are formed on the wafer at a portion corresponding to each semiconductor chip 110. As shown in FIG. 20(b), a protective film 138 may be patterned on one surface of the wafer 5. In addition, after opening a portion of the protective film corresponding to the chip pad 111, a seed layer may be formed, and then, after forming a mask pattern, the portion corresponding to the chip pad 111 may be opened again.

In addition, as shown in FIG. 20(c), a second conductive stud 148 may be formed of a material such as copper, and the mask pattern and the seed layer may be removed.

After forming the second conductive studs 148, the other surface of the wafer 5 may be ground as shown in FIG. 20(d), and as shown in FIG. 20(e), individual semiconductor chips 110 may be manufactured by sawing the wafer on which the second conductive stud 148 is formed into individual semiconductor chips 110.

In this case, the protective film 138 may be omitted if necessary.

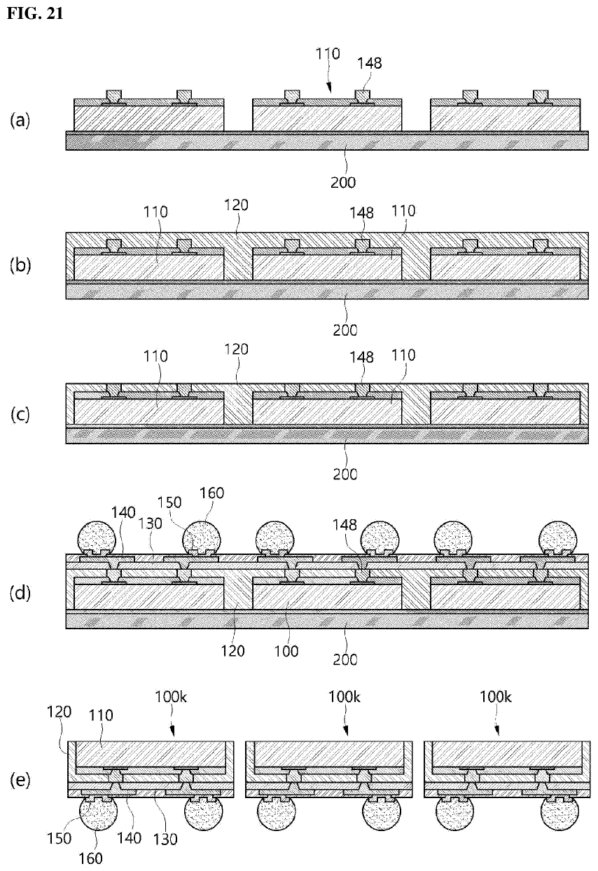

(a) to (e) in FIG. 21 are diagrams showing the manufacturing of a fan-out type wafer level package (WLP) using the individual semiconductor chips manufactured by the above-described method.

First, as shown in FIG. 21(a), a plurality of the semiconductor chips 110 having conductive posts formed thereon may be disposed on a carrier 200. In this case, the second conductive stud 148 of the semiconductor chip 110 may be disposed to face upward.

And, as shown in FIG. 21(b), a protective layer 120 may be molded on the carrier 200 on which the semiconductor chip 110 is disposed so that the semiconductor chip 110 and the second conductive stud 148 are buried in the protective layer 120. After the protective layer 120 is molded, as shown in FIG. 21(c), one surface of the molded protective layer 120 may be ground to expose the second conductive stud 148 to the outside.

After the second conductive stud 148 is exposed, as shown in FIG. 21(d), a redistribution layer 141, an external pad 150, and an external connection terminal 160 may be disposed and formed on one surface of the protective layer 120 in which the second conductive stud 148 is exposed. In this case, a wetting layer 155 may be formed on the external pad 150 by an electroless plating method to improve wettability.

That is, as shown in FIGS. 16 to 19, the external pad 150 may include a structure in which a plurality of layers, such as a lower metal layer 151 and an upper metal layer 152 are stacked. In this case, the lower metal layer 151 may be a seed layer or an adhesive layer for forming the upper metal layer 152, and may be formed of Ti, Cu, Cr, W, Ni, Al, Pd, Au, Sn, or a combination thereof.

In addition, the lower metal layer 151 may have a single metal layer or a multilayer structure including a plurality of metal layers. For example, the lower metal layer 151 may include a first sub metal layer and a second sub metal layer sequentially stacked on the uppermost layer of the insulating pattern 130 and the wiring pattern 140. The first sub metal layer may include a metal material having excellent adhesion properties to the uppermost layer of the insulating pattern 130. For example, the first sub metal layer may include Ti, Cu, Cr, W, Ni, Al, Pd, Au, and Sn, but is not limited thereto. The second sub metal layer may function as a seed layer for forming the upper metal layer. For example, the second sub metal layer may include Cu, but is not limited thereto.

The upper metal layer 152 may be provided on the lower metal layer 151. For example, the upper metal layer 152 may be formed by a plating method using the lower metal layer 151 as a seed. The upper metal layer 152 may have a pillar shape erected on the uppermost layer of the insulating pattern 130, and may have a concave structure in which the central portion of the upper surface is depressed. If the upper metal layer 152 has a concave structure, the lower metal layer 151 may have a correspondingly stepped structure.

A wetting layer 155 (refer to FIGS. 18 and 19) may be formed on the upper metal layer 152 by electroless plating a metal having excellent wettability to exhibit excellent adhesion to the external connection terminal 160. For example, the upper metal layer 152 may include Cu, Au, Sn, or a combination alloy thereof, but is not limited thereto.

And, the external pad 150 may have various shapes, such as a planar shape or a concave shape, as shown in FIGS. 6 to 19 described above.

Meanwhile, the external connection terminal 160 may have a shape that completely covers a portion protruding above the upper surface of the external pad 150, that is, a surface contact type. In this case, the external connection terminal 160 may cover the upper surface and the sidewall of the protrusion portion of the external pad 150. In this case, the sidewall of the protrusion portion may refer to a side surface portion of the protrusion portion protruding above the upper surface of the uppermost layer of the insulating pattern 130.

For example, during a reflow process for forming the external connection terminal 160, a surface contact type external connection terminal 160 may be formed by proceeding with the reflow process in a state in which a metal material layer having excellent wettability (a wetting layer 155) is formed on the external pad 150 to enhance the flowability of the external connection terminal 160.

For a detailed description of the external connection terminal 160, reference will be made to the above description.

After the redistribution layer 141, the external pad 150, and the external connection terminal 160 are disposed, as shown in FIG. 21(e), a step of sawing the protective layer 120 on which the redistribution layer 141, the external pad 150, and the external connection terminal 160 are formed, in units of each individual semiconductor chip 110 may be performed to manufacture an individual semiconductor package 100k. In this case, the carrier 200 may be removed before or after the protective layer 120 is sawed.

Meanwhile, although the above-described manufacturing method is described based on the FOWLP method, it may also be applied to a panel level package (PLP) method. In the FOWLP method, a circular carrier is used as the carrier 200, but in the panel level package method, a quadrangular-shaped carrier may be applied instead of the circular carrier.

That is, a plurality of semiconductor chips 110 having conductive posts formed thereon may be disposed on a quadrangular carrier 200 in (a) of FIG. 21, and as shown in (b) and (c) of FIG. 21, after the protective layer 120 is molded on the carrier 200, the protective layer may be ground to expose the second conductive stud to the outside.

After that, the carrier 200 may be attached with a protective film, and on the upper side thereof, as shown in FIG. 21(d), a redistribution layer 141, an external pad 150, and an external connection terminal 160 may be disposed and formed on one surface of the protective layer 120 in which the second conductive stud 148 is exposed. In this case, a wetting layer may be formed on the external pad 150 by an electroless gold plating method to improve wettability.

Thereafter, an individual semiconductor package may be manufactured by removing the carrier 200 and sawing the semiconductor package.

In this case, the carrier 200 may be formed of various materials such as Glass Fiber Substrate (GFS), PCB, Glass, EMC, Ceramic, Basalt, Epoxy, PI, and metal.

In addition, the carrier 200 may have a square shape of various sizes, such as width x length 300×300 mm or 600×600 mm. Alternatively, it is not necessarily square, and may be a rectangle having different widths and lengths as needed.

Alternatively, if necessary, a plurality of carriers 200 may be sequentially arranged to form a carrier having a larger size.

In addition, after mounting one or more semiconductor chips 110 on a small carrier, primary molding may be performed, and after placing a plurality of molding bodies on a large carrier, secondary molding may be performed, and after grinding and redistributing are performed, sawing into each individual chip unit may be possible.

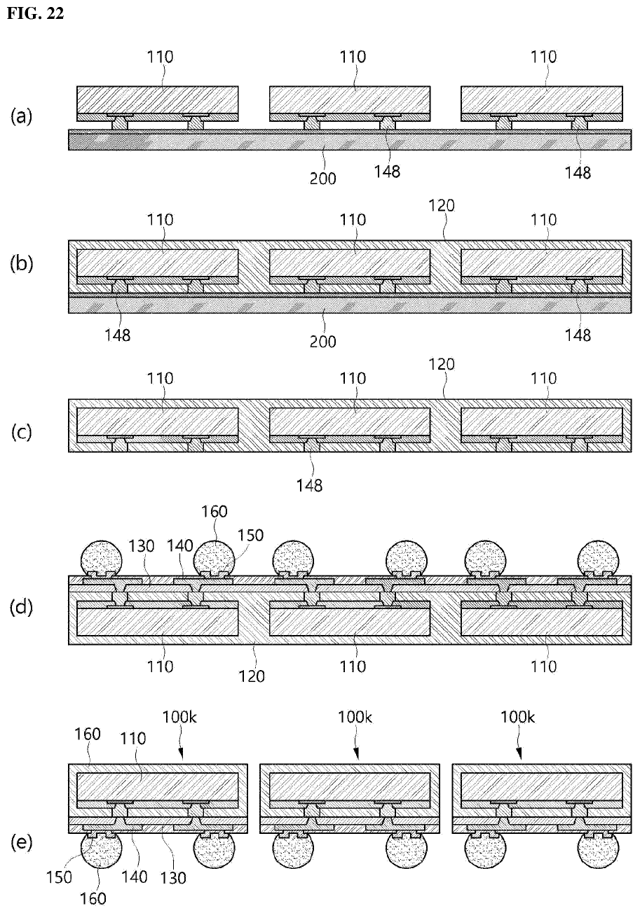

(a) to (e) in FIG. 22 are diagrams showing the manufacturing of a fan-out type wafer level package (WLP) in a face down method using the individual semiconductor chips manufactured by the above-described method.

First, as shown in FIG. 22(a), a plurality of the semiconductor chips 110 having the second conductive stud 148 formed thereon may be disposed on a carrier 200. In this case, the second conductive stud 148 of the semiconductor chip 110 may be disposed to face the carrier 200 at the lower side.

And, as shown in FIG. 22(b), a protective layer 120 may be molded on the carrier on which the semiconductor chip 110 is disposed so that the semiconductor chip 110 and the second conductive stud 148 are buried in the protective layer 120. In this case, since the end of the second conductive stud 148 is in contact with the carrier 200, the end of the second conductive stud 148 may form the same plane as the protective layer 120 without being buried in the protective layer 120. Accordingly, as shown in FIG. 22(c), when the carrier 200 is removed, the end of the second conductive stud 148 may be exposed while forming the same plane as the protective layer 120.

And, after the carrier 200 is removed, as shown in FIG. 22(d), a redistribution layer 141, an external pad 150, and an external connection terminal 160 may be disposed and formed on one surface of the protective layer 120 in which the second conductive stud 148 is exposed. In this case, a wetting layer may be formed on the external pad 150 by an electroless gold plating method to improve wettability.

After the redistribution layer 141, the external pad 150, and the external connection terminal 160 are disposed, as shown in FIG. 22(e), a step of sawing the protective layer 120 on which the redistribution layer 141, the external pad 150, and the external connection terminal 160 are formed, in units of each individual semiconductor chip may be performed to manufacture an individual semiconductor package 100k.

As described above, preferred embodiments according to the present invention have been examined, and it is obvious to those skilled in the art that the present invention can be embodied in other specific forms without departing from the spirit or scope of the invention in addition to the above-described embodiments. Therefore, the above-described embodiments are to be construed as illustrative rather than restrictive, and accordingly, the present invention is not limited to the above description and may be modified within the scope of the appended claims and their equivalents.

<Description of Symbols>

| | |
|---|---|
| 100: semiconductor package | 110: semiconductor chip |
| 111: chip terminal | 120: protective layer |
| 130: insulating pattern | 131: first insulating layer |
| 132: second insulating layer | 133: third insulating layer |
| 140: wiring pattern | 141: wiring layer |
| 142: first conductive via | 143: second conductive via |
| 150: external pad | 160: external connection terminal |

1. A semiconductor package, comprising:
a semiconductor chip having a plurality of chip terminals formed on one surface thereof;
a redistribution layer electrically connected to the chip terminal and for electrically connecting the chip terminal to an external device;
an insulating layer formed to cover the redistribution layer;
an external pad provided on the insulating layer and formed to be electrically connected to the redistribution layer; and
an external connection terminal formed on the external pad and contacting an external device;
wherein the external connection terminal is formed to be in contact with one surface and a side surface of the external pad exposed to the outside of the insulating layer.

2. The semiconductor package of claim 1, wherein a wetting layer having excellent wettability is formed on one surface and a side surface of the external pad in contact with the external connection terminal.

3. The semiconductor package of claim 2, wherein the wetting layer is made of at least one or more of Au, Pd, Ni, Cu, Sn, Ti, Cr, W, and Al.

4. The semiconductor package of claim 1, wherein the external connection terminal is formed to be in surface contact with an upper surface of the insulating layer on the outer periphery of a side surface of the external pad.

5. The semiconductor package of claim 1,
further comprising a conductive post extending in a vertical direction, to electrically connect the chip terminal and the redistribution layer.

6. The semiconductor package of claim 5,
further comprising a protective layer formed to cover the one surface of the semiconductor chip,
wherein the conductive post penetrates the protective layer covering the one surface of the semiconductor chip to electrically connect the chip terminal and the redistribution layer.

7. A method for manufacturing a semiconductor package, comprising:
forming a protective film on one surface of a wafer before a plurality of semiconductor chips are cut, and exposing chip pads of the semiconductor chips;
forming conductive posts on the exposed chip pads; and
sawing the wafer on which the conductive posts are formed into individual semiconductor chips.

8. The method for manufacturing a semiconductor package of claim 7, further comprising:
disposing a plurality of the individual semiconductor chips on which the conductive posts are formed, on a carrier;
molding a protective layer on the carrier on which the semiconductor chip is disposed;
exposing the conductive post of the semiconductor chip molded to the protective layer;
forming a redistribution layer, an external pad, and an external connection terminal on one surface of the protective layer on which the conductive post is exposed; and
sawing the protective layer on which the redistribution layer, the external pad, and the external connection terminal are formed, in units of each individual semiconductor chip.

9. The method for manufacturing a semiconductor package of claim 8,
wherein the disposing a plurality of semiconductor chips on the carrier is a step of disposing a plurality of semiconductor chips on the carrier such that the conductive post faces upward, and
the exposing the conductive post of the semiconductor chip molded to the protective layer is a step of grinding one surface of the molded protective layer so that the conductive post is exposed to the outside.

10. The method for manufacturing a semiconductor package of claim 8,
wherein the disposing a plurality of semiconductor chips on the carrier is a step of disposing the conductive post in contact with the carrier, and
the exposing the conductive post of the semiconductor chip molded to the protective layer is a step of removing the carrier to expose the conductive post after the protective layer is molded.

11. The method for manufacturing a semiconductor package of claim 8,
wherein the disposing a plurality of semiconductor chips on which the conductive posts are formed, on a carrier is a step of disposing a plurality of small panels on which a plurality of semiconductor chips are disposed, on the carrier, the small panel having a size smaller than that of the carrier.

12. The method for manufacturing a semiconductor package of claim 8,
wherein the disposing a plurality of semiconductor chips on which the conductive posts are formed, on a carrier is a step of disposing a plurality of molding bodies on which a plurality of semiconductor chips are molded on the carrier.

13. The method for manufacturing a semiconductor package of claim 8, wherein the disposing a plurality of the individual semiconductor chips on which the conductive posts are formed, on a carrier is a step of disposing a plurality of molding bodies formed on a small panel on which a plurality of semiconductor chips are disposed, on the carrier, the small panel having a size smaller than that of the carrier.

14. The method for manufacturing a semiconductor package of claim 8, wherein the carrier and the small panel have a circular or quadrangular shape.

15. The method for manufacturing a semiconductor package of claim 8, wherein a wetting layer is formed on one surface of the external pad in contact with the external connection terminal by an electroless plating method.

16. The method for manufacturing a semiconductor package of claim 15, wherein the external connection terminal is disposed on one surface of the external pad on which the wetting layer is formed, and is formed to be in contact with one surface and a peripheral side surface of the external pad and a side surface of the external pad.
